(19) United States
(12) Patent Application Publication
(10) Pub. No.: US 2014/0141569 A1
(43) Pub. Date: May 22, 2014

(54) SEMICONDUCTOR DEVICES HAVING THROUGH-VIA AND METHODS OF FABRICATING THE SAME

(71) Applicant: Samsung Electronics Co., Ltd., Suwon-Si (KR)

(72) Inventors: Chajea JO, Bucheon-si (KR); Ji Hwang KIM, Bucheon-si (KR); Tae Hong MIN, Yongin-si (KR); Tae-Sub CHANG, Seoul (KR); Taeje CHO, Hwaseong-si (KR)

(73) Assignee: SAMSUNG ELECTRONICS CO., LTD., Suwon-Si (KR)

(21) Appl. No.: 14/018,630

(22) Filed: Sep. 5, 2013

(30) Foreign Application Priority Data
Nov. 16, 2012 (KR) 10-2012-0130441

(51) Int. Cl. H01L 21/768; H01L 21/50

(52) U.S. Cl. CPC H01L 21/76877; H01L 21/50
USPC 438/109; 438/613

(57) ABSTRACT

In a method of fabricating a semiconductor device, a first sacrificial through-via is formed to fill a first via-hole extending from a first surface of a first substrate toward a second surface of the first substrate opposite the first surface. The first surface of the first substrate is bonded to a carrier. The first sacrificial through-via is exposed, and the first sacrificial through-via is selectively removed. After selectively removing the first sacrificial through-via, a conductive through-via is formed to fill the first via-hole.

### CROSS-REFERENCE TO RELATED APPLICATIONS

This U.S. non-provisional patent application claims priority under 35 U.S.C. §119 to Korean Patent Application No. 10-2012-0130441, filed on Nov. 16, 2012, the entirety of which is incorporated by reference herein.

### BACKGROUND

1. Field

Some example embodiments of the inventive concepts relate to a semiconductor device and a method of fabricating the same and, more particularly, to a semiconductor device having a through-via and a method of fabricating the same.

2. Description of the Related Art

In semiconductor techniques, a through-silicon-via (TSV) technique has been developed to supplement a bonding wire technique. Generally, the TSV technique adopts a via-last scheme or a via-middle scheme. In the via-last scheme, the TSV may be formed after an integrated circuit and a metal interconnection are formed. In the via-middle scheme, the TSV may be foamed after the formation of the integrated circuit and before the formation of the metal interconnection. In the via-middle scheme, the metal interconnection may be formed after the formation of the TSV. In this case, a pumping phenomenon where a top end of the TSV protrudes may occur by a thermal stress and/or thermal expansion of the TSV in a thermal process required for the formation of the metal interconnection.

### SUMMARY

Some example embodiments of the inventive concepts provide semiconductor devices and methods of fabricating the same capable of stably thinning and of improving reliability without metal contamination.

According to an example embodiment, a method of fabricating a semiconductor device includes forming a first sacrificial through-via filling a first via-hole in a first substrate, the first sacrificial through-via extending from a first surface of the first substrate toward a second surface of the first substrate opposite the first surface, bonding the first surface of the first substrate to a carrier, exposing an end portion of the first sacrificial through-via adjacent to the second surface of the first substrate, selectively removing the first sacrificial through-via, and forming a first conductive through-via filling the first via-hole after the first sacrificial through-via is selectively removed.

In an example embodiment, the first sacrificial through-via may be selectively removed by at least one of a dry etching process, a wet etching process, and a sublimating process.

In an example embodiment, the first sacrificial through-via may be formed of a polymer capable of being sublimated.

In an example embodiment, the method may further include forming a first insulating layer on the second surface of the first substrate, the first insulating layer not covering the exposed first sacrificial through-via.

In an example embodiment, the method may further include forming a via-insulating layer between the first substrate and the first sacrificial through-via.

In an example embodiment, the method may further include forming an under bump metallurgy layer between the first conductive through-via and the via-insulating layer.

In an example embodiment, the method may further include forming a first terminal on the first surface of the first substrate. The first terminal may he electrically connected to the first conductive through-via.

In an example embodiment, the method may further include forming a second terminal on the second surface of the first substrate. The second terminal may be electrically connected to the first conductive through-via.

In an example embodiment, the first conductive through-via and the second terminal may be formed simultaneously.

In an example embodiment, the method may further include stacking a second semiconductor device on the first substrate, the second semiconductor device including a second sacrificial through-via filling a second via-hole in the second semiconductor device, the second sacrificial through-via extending from a first surface of the second semiconductor device toward a second surface opposite the first surface of the second semiconductor device, and a first terminal on the first surface of the second semiconductor device, the first terminal of the second semiconductor device electrically connected to the second terminal of the first substrate, forming an adhesive layer between the second semiconductor device and the first substrate, exposing an end portion of the second sacrificial through-via adjacent to the second surface of the second semiconductor device, selectively removing the second sacrificial through-via, and forming a second conductive through-via filling the second via-hole after the second sacrificial through-via is selectively removed.

In an example embodiment, the second semiconductor device may be an individual semiconductor device, the adhesive layer may be formed to include an underfill, and the adhesive layer may be formed extending to cover at least portions of sidewalls of the second semiconductor device.

In an example embodiment, the second semiconductor device may be stacked on a second substrate, and the adhesive layer may be a non-conductive film.

In an example embodiment, the method may further include forming a molding part covering the second semiconductor device and the second surface of the first substrate.

In an example embodiment, the method may further include cutting the molding part and the first substrate to form stacked semiconductor devices separate from each other.

In an example embodiment, the method may further include mounting the stacked semiconductor devices on a wiring substrate, the first surface of the first substrate of the stacked semiconductor devices facing the wiring substrate.

According to another example embodiment, a method of fabricating a semiconductor device includes forming a sacrificial through-via filling a via-hole in a substrate, the sacrificial through-via extending from a first surface of the substrate toward a second surface of the substrate opposite the first surface, forming a metal interconnection on the first surface of the substrate, the metal interconnection electrically connected to the sacrificial through-via, and after forming the metal interconnection, selectively removing the sacrificial through-via from the via-hole and forming a conductive through-via therein.

In another example embodiment, the method may further include bonding the first surface of the substrate to a carrier, and exposing an end portion of the sacrificial through-via adjacent to the second surface of the substrate before the selectively removing the sacrificial through-via.

In another example embodiment, the sacrificial through-via may be selectively removed by at least one of a dry etching process, a wet etching process, and a sublimating process.

In another example embodiment, the method may further include forming a via-insulating layer between the substrate and the sacrificial through-via.

In another example embodiment, the method may further include forming an under bump metallurgy layer between the conductive through-via and the via-insulating layer.

### BRIEF DESCRIPTION OF THE DRAWINGS

The inventive concepts will become more apparent in view of the attached drawings and accompanying detailed description.

FIG. 1A is a cross-sectional view illustrating a semiconductor device according to an example embodiment of the inventive concepts;

FIG. 1B is an enlarged view of a portion ‘A’ of FIG. 1A;

FIGS. 2 to 16 are enlarged views of a portion ‘A’ of FIG. 1A to illustrate a method of fabricating a semiconductor device according to an example embodiment of the inventive concepts;

FIGS. 17A to 26A are cross-sectional views illustrating a method of fabricating a semiconductor package according to another example embodiment of the inventive concepts;

FIGS. 17B to 26B are cross-sectional views illustrating a method of fabricating a semiconductor package according to yet another example embodiment of the inventive concepts;

FIG. 27 is a plan view illustrating a package module according to an example embodiment of the inventive concepts;

FIG. 28 is a schematic block diagram illustrating a memory card according to an example embodiment of the inventive concepts;

FIG. 29 is a schematic block diagram illustrating an electronic system according to an example embodiment of the inventive concepts; and

FIG. 30 is a perspective view illustrating an electronic device according to an example embodiment of the inventive concepts.

### DETAILED DESCRIPTION

The inventive concepts will now be described more fully hereinafter with reference to the accompanying drawings, in which some example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, example embodiments are provided only to disclose the inventive concepts and let those skilled in the art know the category of the inventive concepts. In the drawings, example embodiments of the inventive concepts are not limited to the specific examples provided herein and are exaggerated for clarity.

The terminology used herein is for the purpose of describing particular embodiments only and is not intended to limit the inventive concepts. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the example embodiments in the detailed description will be described with sectional views as ideal example views of the inventive concepts. Accordingly, shapes of the example views may be modified according to manufacturing techniques and/or allowable errors. Therefore, the inventive concepts are not limited to the specific shape illustrated in the example views, but may include other shapes that may be created according to manufacturing processes. Areas illustrated in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These teens are only used to distinguish one element from another element. Thus, a first element in some example embodiments could be termed a second element in other example embodiments without departing from the teachings of the inventive concepts. Example embodiments of the inventive concepts explained and illustrated herein include their complementary counterparts. The same reference numerals or the same reference designators denote the same elements throughout the specification.

Moreover, example embodiments are described herein with reference to cross-sectional illustrations and/or plane illustrations that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

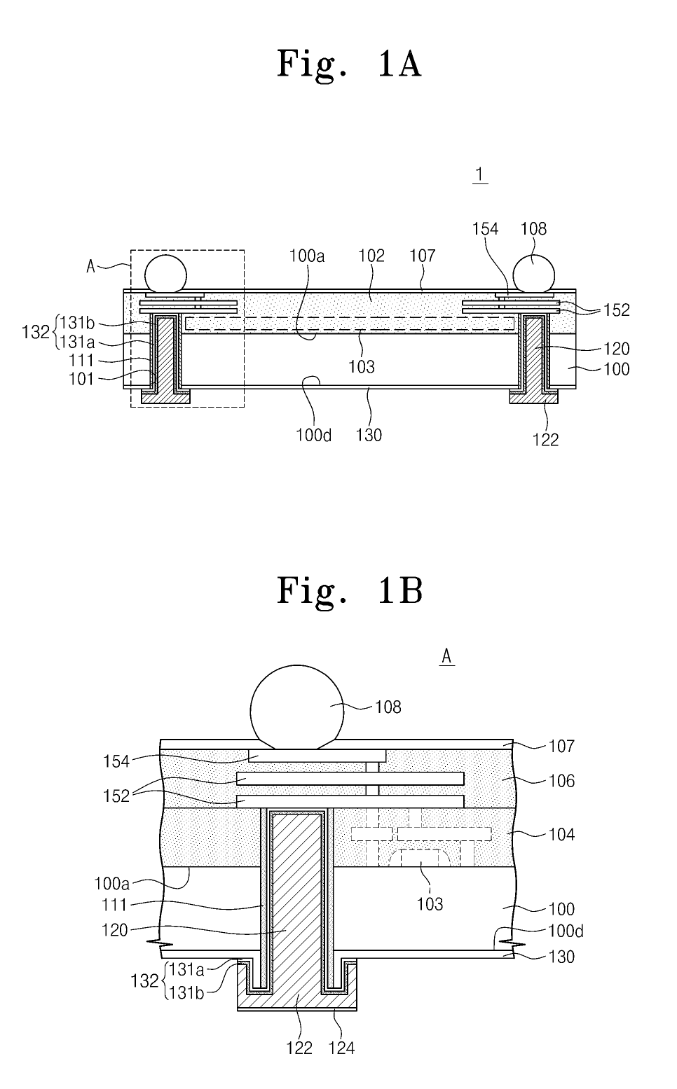

FIG. 1A is a cross-sectional view illustrating a semiconductor device according to an example embodiment of the inventive concepts, and FIG. 1B is an enlarged view of a portion ‘A’ of FIG. 1A.

Referring to FIGS. 1A and 1B, a semiconductor device 1 may include an electrical connection part A for transmitting an electrical signal. The electrical connection part A may include a through-via 120 filling a via-hole 101 substantially vertically penetrating a substrate 100. The through-via 120 is formed of a conductive material. A bottom end portion of the through-via 120 may protrude from a non-active surface 100d of the substrate 100. A via-insulating layer 111 may be provided between the through-via 120 and the substrate 100. The via-insulating layer 111 electrically insulates the through-via 120 from the substrate 100.

An under bump metallurgy (UBM) layer 132 may be provided between the through-via 120 and the via-insulating layer 111. The UBM layer 132 may include a barrier layer 131a and a seed layer 131b. The barrier layer 131a may prevent or inhibit a constituent (e.g., copper (Cu)) of the through-via 120 from being diffused into the via-insulating layer 111 and/or the substrate 100. The seed layer 131b may be used as a seed for the formation of the through-via 120. The UBM layer 132 may include an exposed portion at an active surface 100a of the substrate 100. Additionally, the UBM layer 132 may extend between the non-active surface 100d of the substrate 100 and a lower terminal 122.

The semiconductor device 1 may further include at least one of an upper terminal 108 and the lower terminal 122 which are electrically connected to the through-via 120. The upper terminal 108 may be disposed on the active surface 100a of the substrate 100, and the lower terminal 122 may be disposed on the non-active surface 100d of the substrate 100. Each of the upper and lower terminals 108 and 122 may include a solder ball, a solder bump, a re-distribution wire, or a pad. In an embodiment, the upper terminal 108 may include the solder ball, and the lower terminal 122 may include the pad. The lower terminal 122 and the through-via 120 may be formed simultaneously. A gold plating layer 124 may be further formed on the lower terminal 122. The gold plating layer 124 may increase electrical conductivity of the lower terminal 122.

An integrated circuit 103, a metal interconnection 152, and an interlayer insulating layer 102 may be disposed on the active surface 100a of the substrate 100. The metal interconnection 152 may be a single-layered or multi-layered structure and may be electrically connected to the integrated circuit 103. The interlayer insulating layer 102 may cover the integrated circuit 103 and the metal interconnection 152. The interlayer insulating layer 102 may include a first interlayer insulating layer 104 and a second interlayer insulating layer 106. An upper insulating layer 107 may be disposed on the interlayer insulating layer 102. The upper insulating layer 107 may open a bonding pad 154 to which the upper terminal 108 is connected. The metal interconnection 152 is electrically connected to the through-via 120, such that the integrated circuit 103 may be electrically connected to the through-via 120. The through-via 120 may be disposed around or in the integrated circuit 103. A lower insulating layer 130 opening the through-via 120 may be disposed on the non-active surface 100d of the substrate 100.

The substrate 100 may be a chip level substrate or a wafer level substrate. The integrated circuit 103 may be a memory circuit, a logic circuit, or any combination thereof.

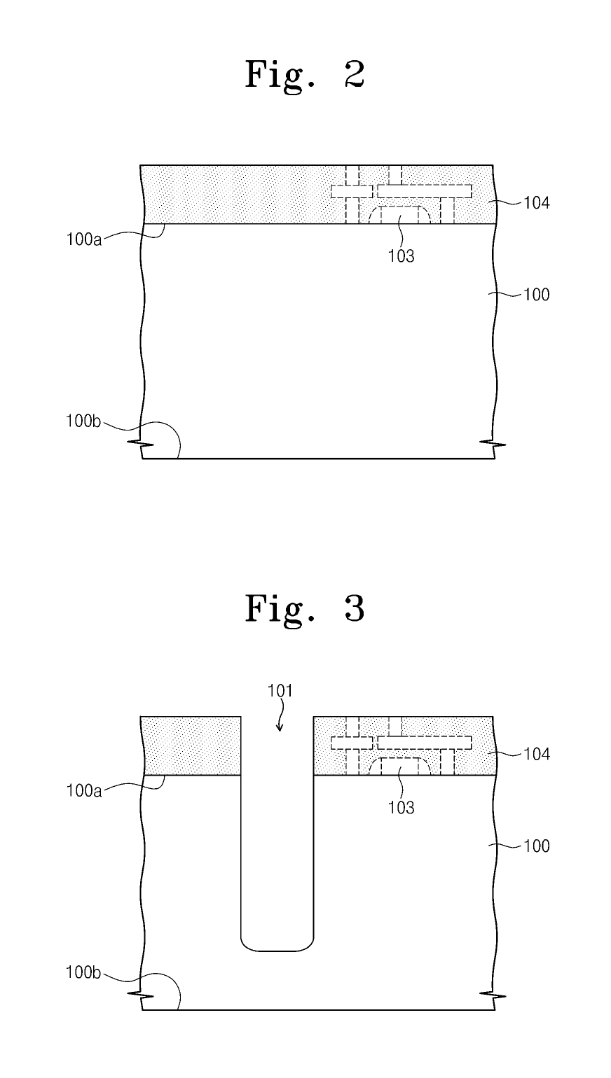

FIGS. 2 to 16 are enlarged views of a portion ‘A’ of FIG. 1A to illustrate a method of fabricating a semiconductor device according to an example embodiment of the inventive concepts.

Referring to FIGS. 2 and 3, a via-hole 101 may be formed in a substrate 100. The substrate 100 may have a top surface 100a and a first bottom surface 100b opposite to the top surface 100a. An integrated circuit 103 may be formed on the top surface 100a of the substrate 100. The substrate 100 may be a semiconductor substrate, for example, a silicon substrate. A first interlayer insulating layer 104 covering the integrated circuit 103 may be formed on the top surface 100a of the substrate 100. The integrated circuit 103 may be a memory circuit, a logic circuit, or any combination thereof. The first interlayer insulating layer 104 may be formed of silicon oxide and/or silicon nitride by a deposition method. The integrated circuit 103 and the first interlayer insulating layer 104 may be formed by front end of line (FEOL) processes.

The via-hole 101 may have a hollow pillar shape opened toward the top surface 100a of the substrate 100 and a depth that does not reach the first bottom surface 100b. The via-hole 101 may be substantially vertical from the top surface 100a to the first bottom surface 100b of the substrate 100. The via-hole 101 may be disposed at the circumference (e.g., a scribe lane) of the integrated circuit 103 or at a region adjacent to the integrated circuit 103. Alternatively, the via-hole 101 may be disposed in a region where the integrated circuit 103 is formed. A dry-etching process or a drilling process may be performed on the first interlayer insulating layer 104 and the substrate 100 to form the via-hole 10.

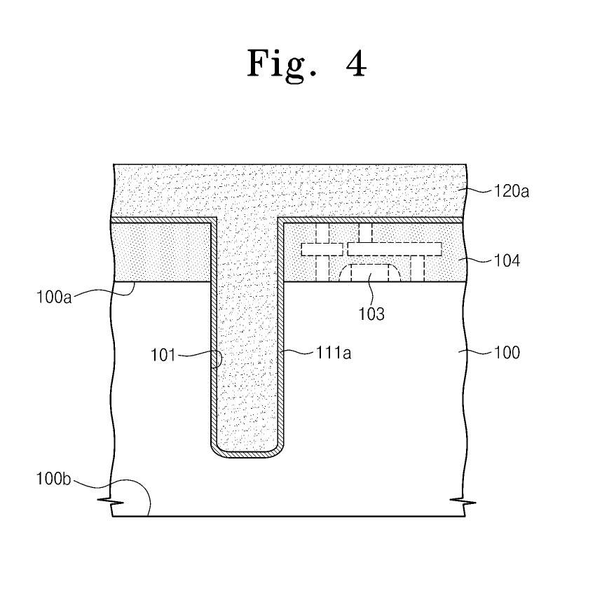

Referring to FIG. 4, an insulating layer 111a may be formed to extend along an inner surface of the via-hole 101, and a sacrificial layer 120a may be formed on the substrate 100 to fill the via-hole 101. The insulating layer 111a may be formed by a chemical vapor deposition (CVD) method, for example, a plasma-enhanced CVD (PECVD) method. For example, the insulating layer 111a may be formed of a silicon oxide layer and/or a silicon nitride layer. The sacrificial layer 120a may be formed of a material having an etch selectivity with respect to the substrate 100 and the insulating layer 111a by a deposition method. For example, the sacrificial layer 120a may be formed of a CVD material having an etch rate different from those of the substrate 100 and the insulating layer 111a or a polymer capable of being sublimated. The CVD material may include a PECVD material or tetraethyl-orthosilicate (TEOS). The polymer capable of being sublimated may be a heat-resistant polymer. The heat-resistant polymer may include phenylene derivatives or fullerenes.

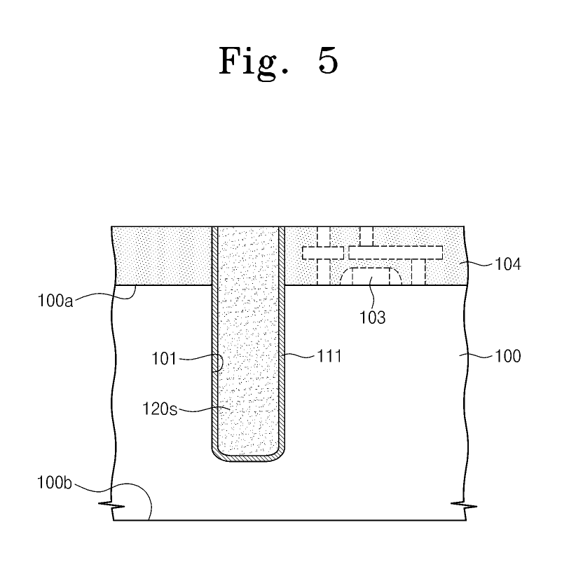

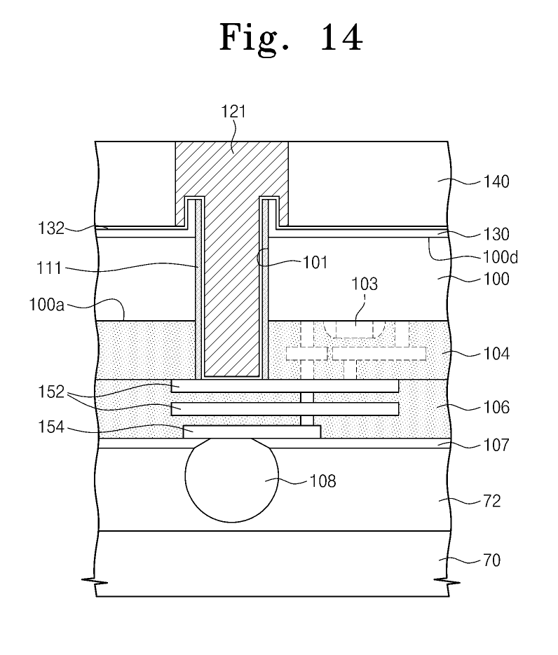

Referring to FIG. 5, the sacrificial layer 120a and the insulating layer 111a may be planarized to expose the first interlayer insulating layer 104. The planarizing process may be performed by an etch-back process or a chemical mechanical polishing (CMP) process. By the planarizing process, the sacrificial layer 120a may be formed into a sacrificial through-via 120s substantially vertically penetrating the first interlayer insulating layer 104 and substrate 100, and the insulating layer 111a may be formed into a via-insulating layer 111 electrically insulating a through-via 120 of FIG. 14 from the substrate 100.

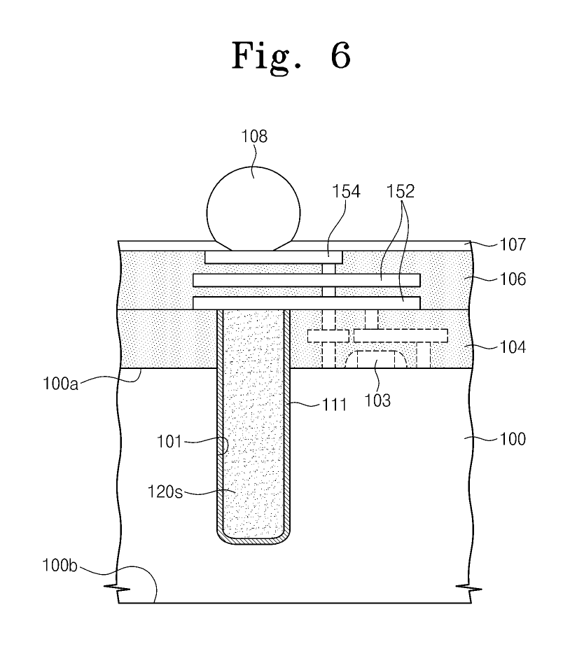

Referring to FIG. 6, back end of line (BEOL) processes may be performed. In an example embodiment, a metal interconnection 152 of a single-layered or multi-layered structure, a bonding pad 154, and a second interlayer insulating layer 106 may be formed on the first interlayer insulating layer 104. The metal interconnection may be connected to the sacrificial through-via 120s, and the bonding pad 154 may be electrically connected to the metal interconnection 152. The second interlayer insulating layer 106 may cover the metal interconnection 152 and the bonding pad 154. A metal such as copper (Cu) and/or aluminum (Al) may be deposited and the deposited metal may be patterned to form the metal interconnection 152 and the bonding pad 154. The second interlayer insulating layer 106 may be formed of the same insulating material as or a similar insulating material to the first interlayer insulating layer 104 by a CVD method. For example, the second interlayer insulating layer 106 may be formed of silicon oxide and/or silicon nitride.

An upper insulating layer 107 may be formed on the second interlayer insulating layer 106. The upper insulating layer 107 may be formed of silicon oxide, silicon nitride, or polymer by a deposition method. The upper insulating layer 107 may be patterned to expose the bonding pad 154. In an embodiment, a bump process may be performed to form an upper terminal 108 connected to the bonding pad 154. The upper terminal 108 may be a solder ball or a solder bump.

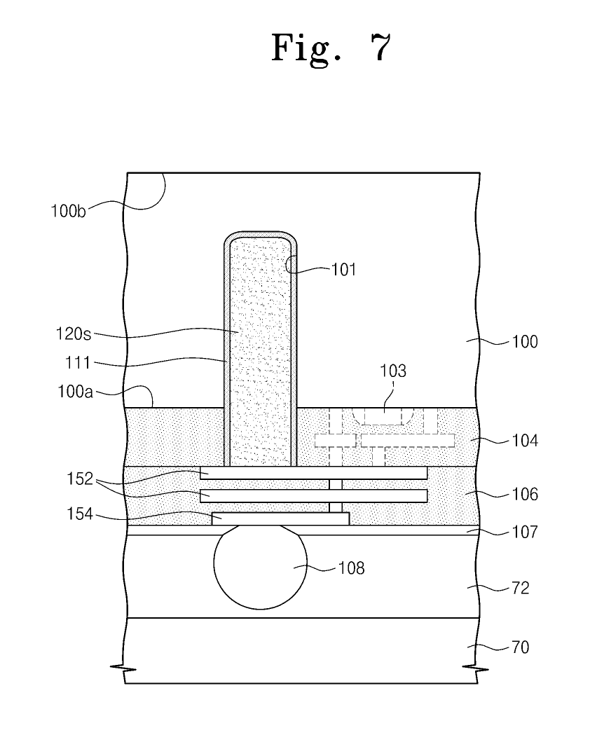

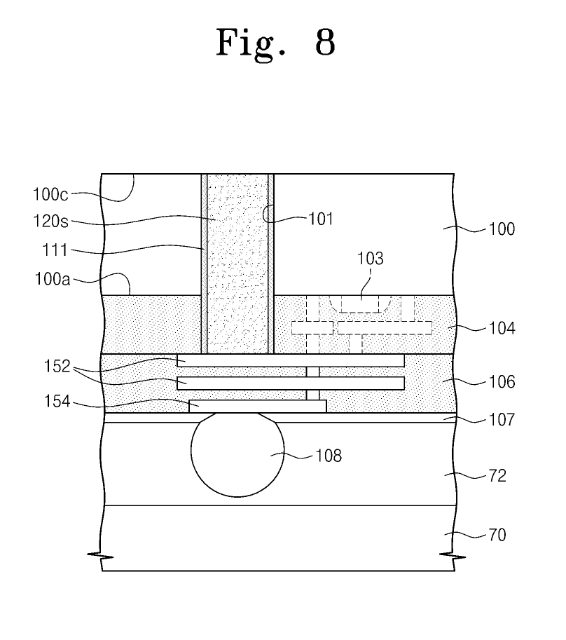

Referring to FIGS. 7 and 8, a first thinning process may be performed on the substrate 100 to expose the sacrificial through-via 120s. For example, the first bottom surface 100b of the substrate 100 may be recessed by an etching process, a CMP process, a grinding process, or any combination thereof The etching process may use an etchant capable of selectively removing a constituent (e.g., silicon) of the substrate 100. The CMP may use slurry capable of selectively removing the constituent of the substrate 100. The first bottom surface 100b may be recessed until a bottom end portion of the sacrificial through-via 120s is exposed. The recessed bottom surface of the substrate 100 is defined as a second bottom surface 100c. The second bottom surface 100c may be closer to the top surface 100a of the substrate 100 as compared with the first bottom surface 100b. In an example embodiment, the recessing process of the first bottom surface 100b may be performed by a direct grinding process. The sacrificial through-via 120s may be formed of polymer. Thus, even though the recessing process is performed by the direct grinding process, metal contamination does not occur on the second bottom surface 100c. Additionally, since the recessing process of the first bottom surface 100b may not be a precision process, the recessing process of the first bottom surface 100b may be performed by the direct grinding process having a relatively small cost. Thus, fabricating costs of the semiconductor device 1 may be reduced.

The process exposing the sacrificial through-via 120s (i.e., the recessing process of the first bottom surface 100b) may be performed in the state that the top surface 100a of the substrate 100 is adhered to a carrier 70 with a first adhesive layer 72 therebetween. The first adhesive layer 72 may include glue. However, the inventive concepts are not limited thereto. The exposing process of the sacrificial through-via 120s may be performed with the top surface 100a of the substrate 100 facing upward. Alternatively, the substrate 100 may be overturned, such that the exposing process may be performed with the top surface 100a facing downward.

The carrier 70 may be a hard substrate (e.g., a glass substrate, a silicon substrate, a metal substrate, or a polymer substrate) or a soft substrate (e.g., an elastic tape). The carrier 70 may support the substrate 100 to prevent or inhibit the substrate 100 from being bent or damaged during the recessing process of the first bottom surface 100b. Additionally, the carrier 70 may protect the metal interconnection 152, the bonding pad 154 and/or the upper terminal 108 disposed on the top surface 100a of the substrate during the recessing process of the first bottom surface 100b.

Before the recessing process is performed, a thickness of the substrate 100 adhered to the carrier 70 may have a range of about 300 μm to about 500 μm. Thus, even though the carrier 70 is not used, an attaching process, a detaching process, a transferring process, and/or a mounting process may be stably performed without warpage of the substrate 100.

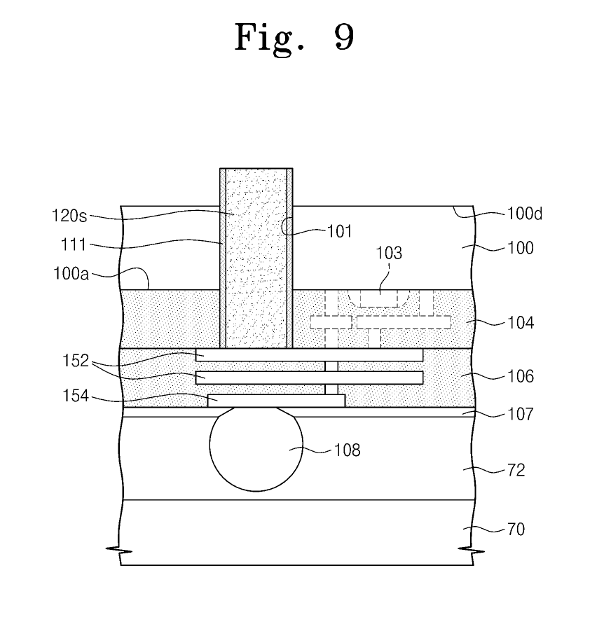

Referring to FIG. 9, a second thinning process may be performed on the substrate 100, so that the sacrificial through-via 120s may protrude. For example, the second bottom surface 100c of the substrate may be additionally recessed by an etching process using an etchant capable of selectively removing a constituent (e.g., silicon) of the substrate 100, a CMP process using slurry capable of selectively removing the constituent of the substrate 100, a grinding process, or any combination thereof. The second bottom surface 100c may be additionally recessed to protrude the bottom end portion of the sacrificial through-via 120s and to form a third bottom surface 100d of the substrate 100. The third bottom surface 100d may be closer to the top surface 100a of the substrate 100 as compared with the second bottom surface 100c. The substrate 100 may have a thickness of about 50 μm or less by the second thinning process. In an example embodiment, the top surface 100a of the substrate 100 corresponds to an active surface, and the third bottom surface 100d of the substrate 100 corresponds to a non-active surface.

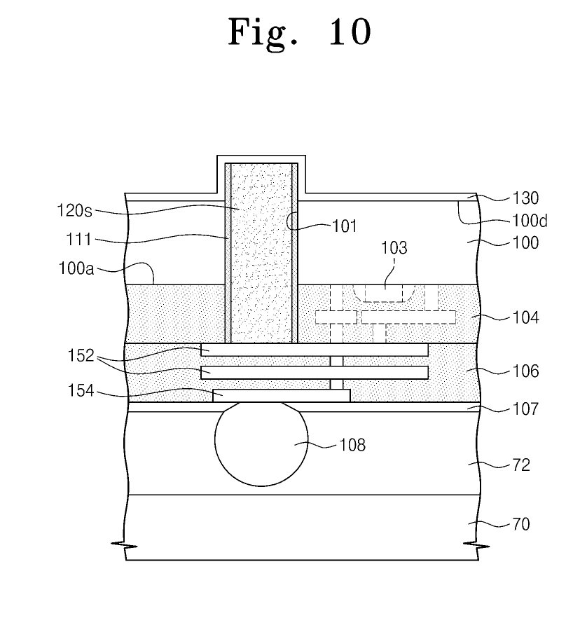

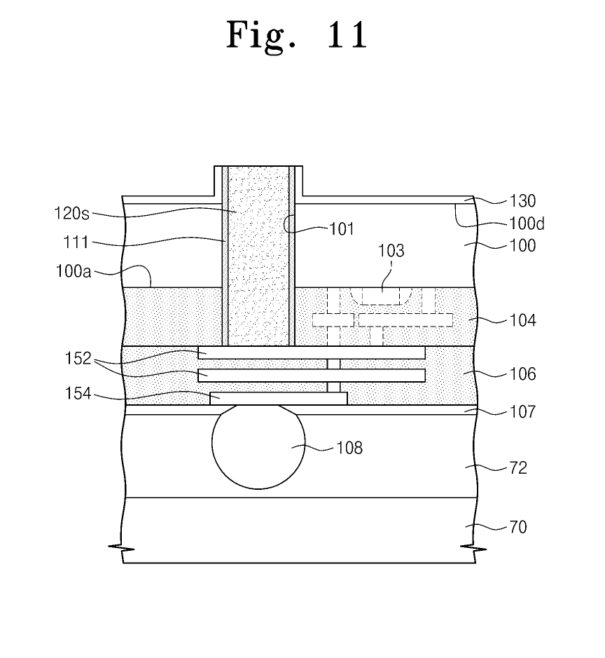

Referring to FIGS. 10 and 11, a lower insulating layer 130 may be formed on the third bottom surface 100d of the substrate 100. For example, the lower insulating layer 130 may be formed of a silicon oxide layer, a silicon nitride layer, and/or a polymer layer by a CVD method. The lower insulating layer 130 may cover the third bottom surface 100d of the substrate 100, the via-insulating layer 111, and the sacrificial through-via 120s. The lower insulating layer 130 may be polished, grinded, or etched to expose the bottom end portion of the sacrificial through-via 120s.

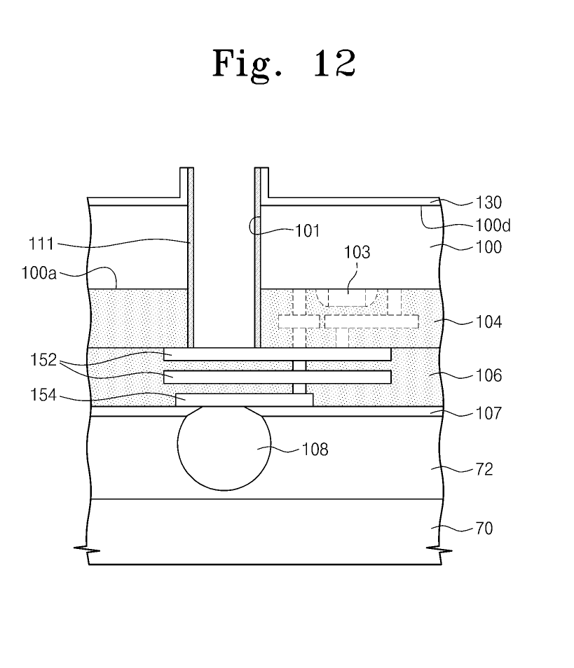

Referring to FIG. 12, the exposed sacrificial through-via 120s may be selectively removed. Since the sacrificial through-via 120s has an etch selectivity with respect to the substrate 100, the via-insulating layer 111, and the lower insulating layer 130, the sacrificial through-via 120s may be selectively removed. The selective removal of the sacrificial through-via 120s may be performed using a dry etching process, a wet etching process, and/or a sublimating process. In an embodiment, the sacrificial through-via 120s may include the polymer capable of being sublimated, as described above. The polymer capable of being sublimated may be a heat-resistant polymer. The heat-resistant polymer may include phenylene derivatives or fullerenes. A sublimating condition of the polymer may be induced through change of a temperature and/or a pressure.

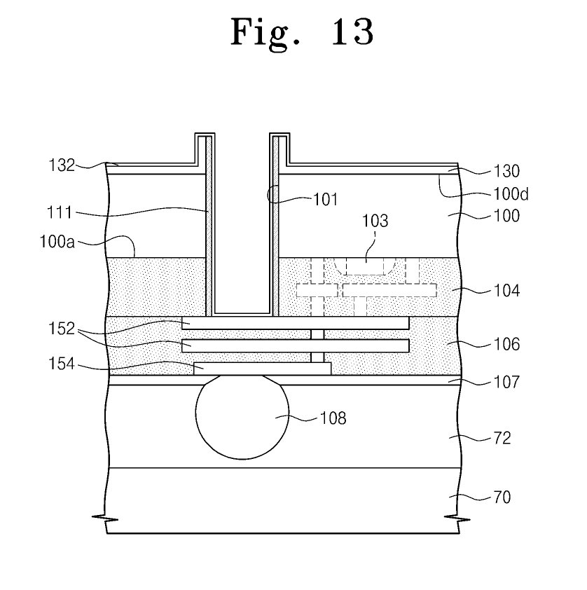

Referring to FIG. 13, an under bump metallurgy (UBM) layer 132 may be formed on the third bottom surface 100d of the substrate 100 and an inner surface of the via-hole 101 from which the sacrificial through-via 120s is removed. The UBM layer 132 may be formed using a physical vapor deposition (PVD) method. The UBM layer 132 may be in direct contact with the metal interconnection 152 exposed by the via-hole 101. The UBM layer 132 may include a barrier layer 131a as illustrated in FIG. 1B preventing or inhibiting diffusion of a constituent (e.g., copper) of a through-via 120 in FIG. 14 and a seed layer 131b also illustrated in FIG. 1B used as a seed for forming the through-via 120 in FIG. 4. The barrier layer 131a in FIG. 1B may be formed of titanium (Ti), titanium nitride (TiN), chromium (Cr), tantalum (Ta), tantalum nitride (TaN), nickel (Ni), or any combination thereof.

Referring to FIG. 14, a photoresist pattern 140 exposing the via-hole 101 may be formed on a third bottom surface 100d of the substrate 100 and a conductive layer 121 may be formed to fill the via-hole 101 and a space on the third bottom surface 100d exposed by the photoresist pattern 140. The conductive layer 121 may be formed of doped poly-silicon, copper (Cu), tungsten (W), and/or aluminum (Al) by a deposition method and/or a plating method. In an example embodiment, the conductive layer 121 may include copper formed by the plating method.

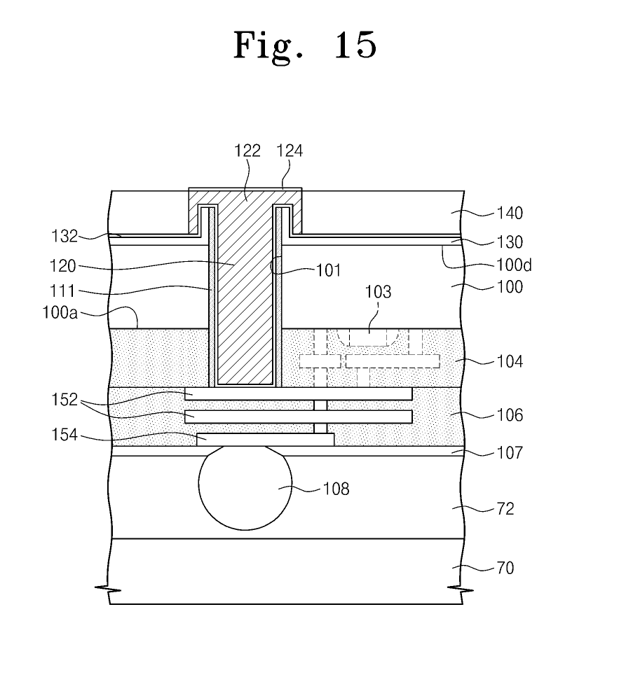

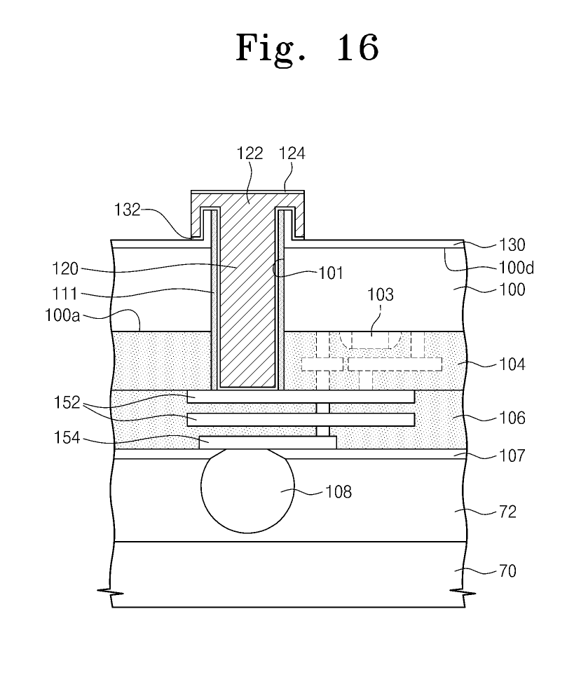

Referring to FIGS. 15 and 16, the conductive layer 121 and the photoresist pattern 140 on the third bottom surface 100d of the substrate 100 may be planarized to form the through-electrode 120 and a lower terminal 122. The through-via 120 may penetrate the first interlayer insulating layer 104 and the substrate 100 so as to be electrically connected to the metal interconnection 152. The lower terminal 122 may be electrically connected to the through-via 120. In other words, the through-via 120 and the lower terminal 122 may be formed at the same time. The lower terminal 122 may have a bonding pad-shape. The planarization process of the conductive layer 120 and 122 and the photoresist pattern 140 may be performed using a fly cutting method. Since the photoresist pattern 140 covers the third bottom surface 100d of the substrate 100, metal contamination does not occur on the third bottom surface 100d of the substrate in the planarization process. Additionally, a surface of the lower terminal 122 may not need a precision process. Thus, the planarization process may be performed using a relatively low-cost method such as the fly cutting method. As a result, the fabricating costs of the semiconductor device 1 may be additionally reduced.

A gold plating layer 124 may be further formed on the lower terminal 122. The gold plating layer 124 may increase electrical conductivity of the lower terminal 122. Additionally, the gold plating layer 124 may allow the lower terminal 122 to be easily bonded to an aluminum pad of a semiconductor device stacked on the lower terminal 122 in a subsequent process by a thermo-compression bonding method. The gold plating layer 124 may be formed using an electroless plating method.

The photoresist pattern 140 and the UBM layer 132 under the photoresist pattern 140 may be removed, and then the substrate 100 may be cut to separate an individual semiconductor device 1 from the carrier 70.

A pumping phenomenon may occur at a metal through-via formed using a conventional via-middle scheme by subsequent processes. Due to the pumping phenomenon, a metal interconnection contacting the metal through-via may delaminate and/or an interface resistance between the metal through-via and the metal interconnection may increase. In a via-last scheme, a high temperature process may be difficult to perform in a state where a substrate is bonded to a supporter, and an alignment problem may occur in a substrate thinning process.

According to an example embodiment of the inventive concepts, the sacrificial through-via 120s may be formed by the via-middle scheme and the metal interconnection 152 may be formed. Thereafter, the sacrificial through-via 120s may be replaced with the through-via 120 by the via-last scheme. Thus, the substrate 100 may be thinned without the metal contamination on the bottom surface of the substrate 100. Additionally, the pumping phenomenon of the through-via 120 caused by thermal stress or thermal expansion may be prevented or inhibited. Moreover, the substrate 100 may be stably thinned. As a result, the stably thinned semiconductor device having improved reliability and the method of fabricating the same may be provided.

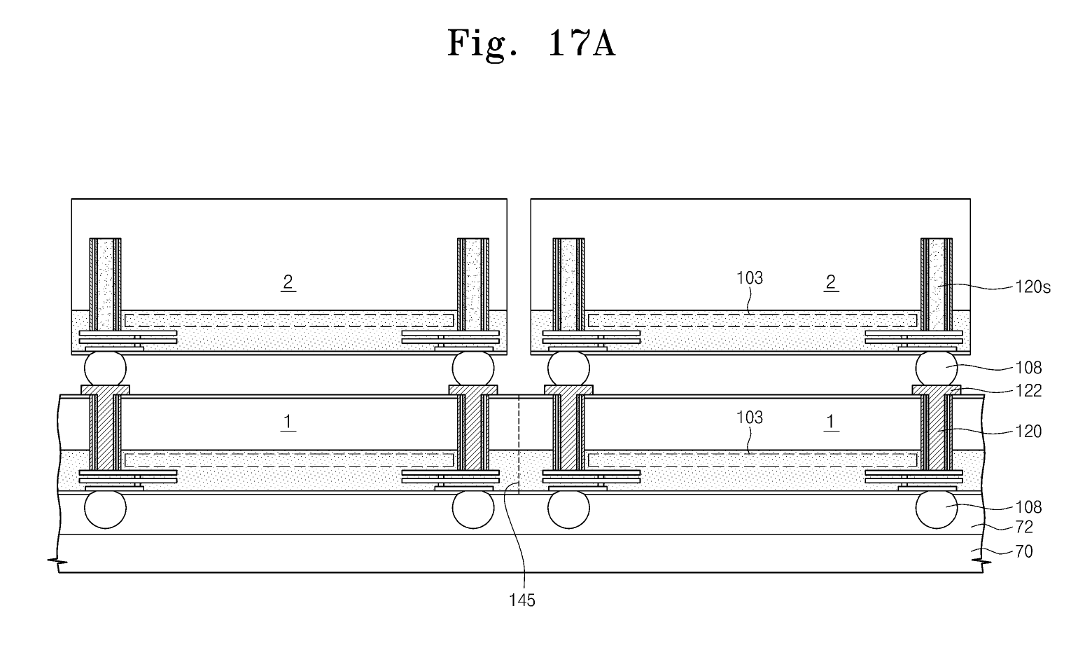

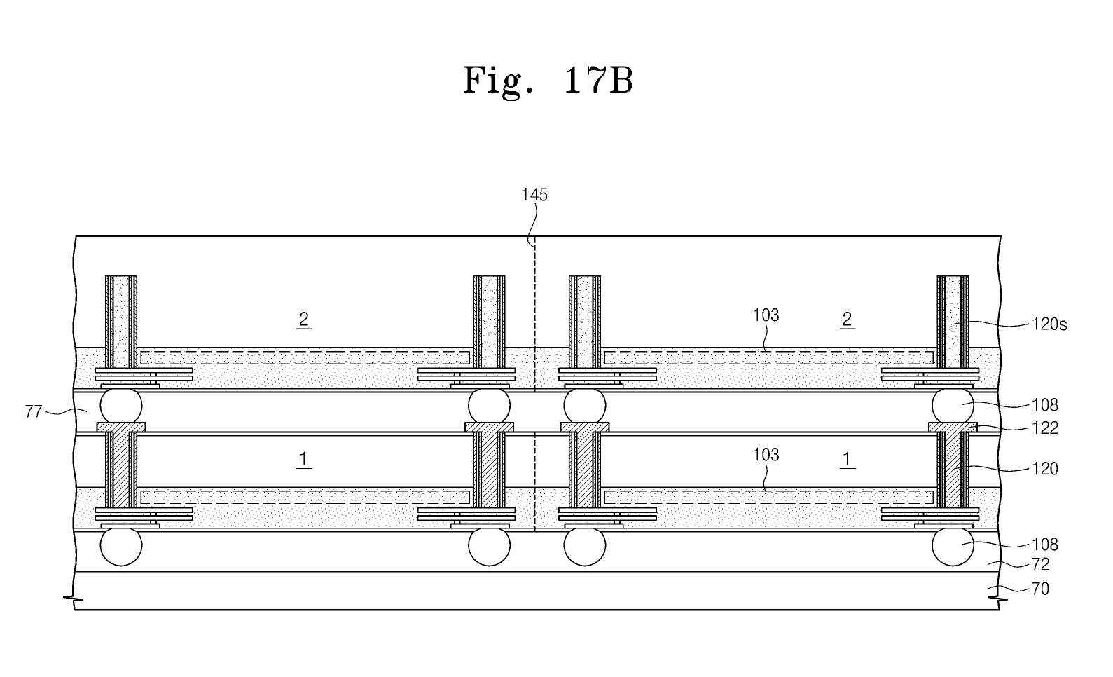

FIGS. 17A to 26A are cross-sectional views illustrating a method of fabricating a semiconductor package according to another example embodiment of the inventive concepts. FIGS. 17B to 26B are cross-sectional views illustrating a method of fabricating a semiconductor package according to yet another example embodiment of the inventive concepts.

Referring to FIGS. 17A and 17B, a first substrate having a plurality of first semiconductor devices 1 may be prepared. Second semiconductor devices 2 may be stacked on the first substrate. The second semiconductor device 2 may have a second sacrificial through-via 120s filling a second via-hole extending from a top surface toward a bottom surface opposite to the top surface of the second semiconductor device 2. The second semiconductor device 2 may be stacked on the first substrate to electrically connect an upper terminal 108 on the top surface of the second semiconductor device 2 to the lower terminal 122 of the first semiconductor device 1.

As illustrated in FIG. 17A, the second semiconductor devices 2 may be individual semiconductor devices separated from each other. Alternatively, as illustrated in FIG. 17B, the second semiconductor devices 2 may be formed on a second substrate. In other words, FIG. 17A illustrates the second semiconductor chips 2 stacked on the first substrate in a chip-on-wafer (COW) manner, and FIG. 17B illustrates the second semiconductor devices 2 stacked on the first substrate in a wafer-on-wafer manner.

A thickness of the stacked second semiconductor device 2 may have a range of about 300 μm to about 500 μm. Attaching, detaching, transferring and/or mounting processes may be stably performed without warpage of the second semiconductor device 2 due to the above thickness of the second semiconductor device 2 even though a carrier is not used.

As illustrated in FIG. 17B, the second substrate may be stacked on the first substrate with a second adhesive layer 77 therebetween. The second adhesive layer 77 may be a non-conductive film (NCF). The non-conductive film may have a characteristic capable of being perforated by the upper terminal 108 of the second semiconductor device 2. Thus, the upper terminal 108 of the second semiconductor device 2 may be electrically connected to the lower terminal 122 of the first semiconductor device 1. The substrate may be cut along a scribe lane 145. Thus, individual stack semiconductor devices may be separated from each other.

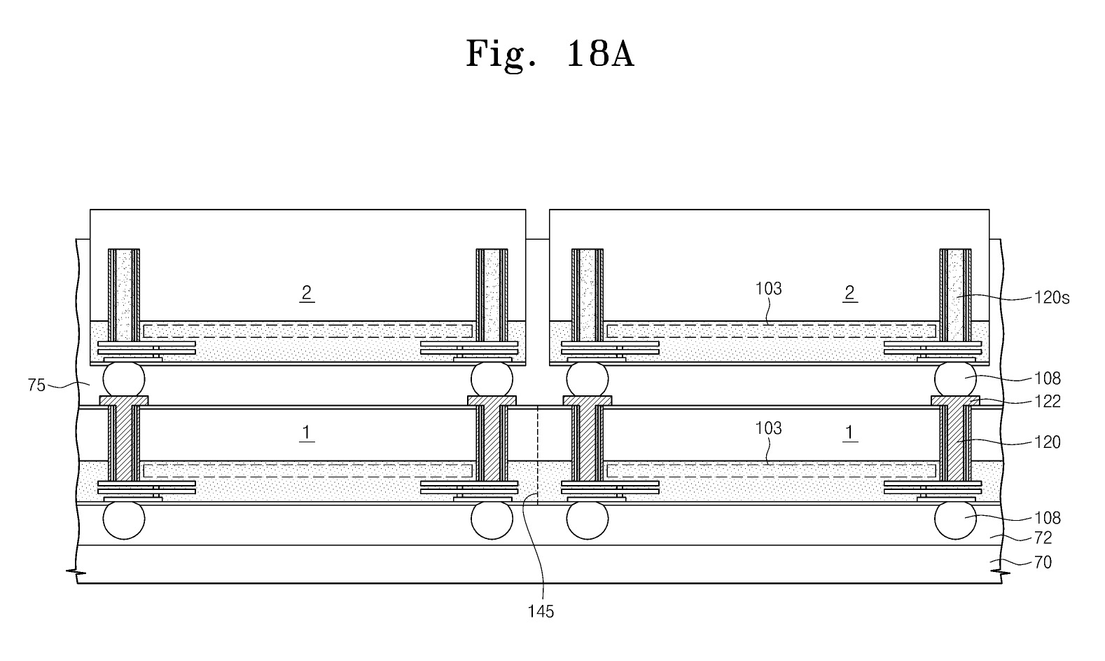

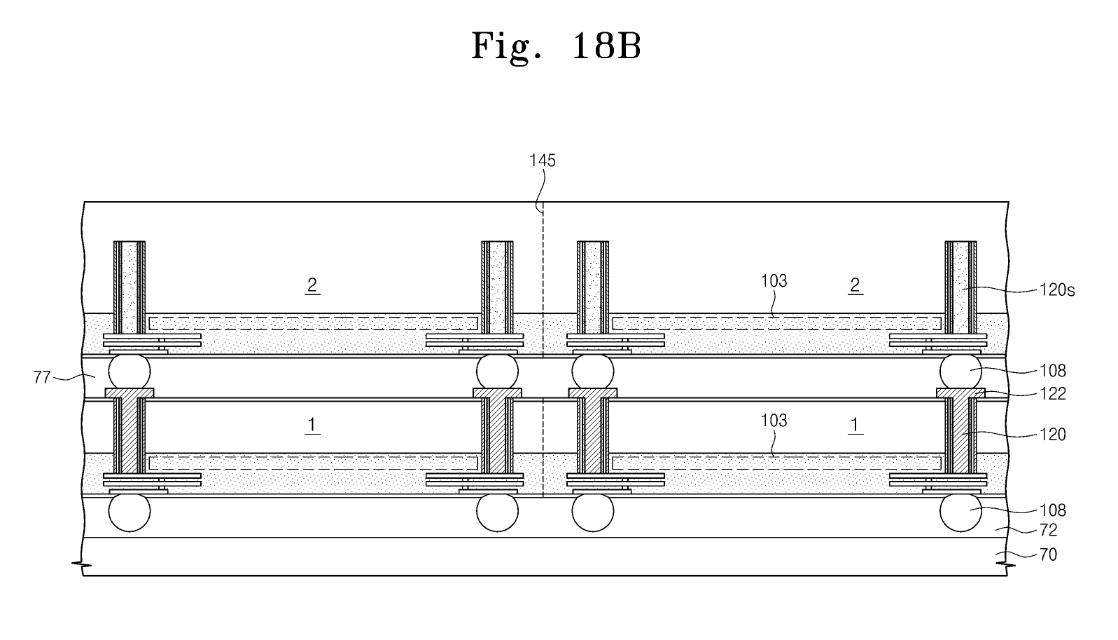

Referring to FIGS. 18A and 18B, a second adhesive layer 75 or 77 may be formed between the second semiconductor device 2 and the first substrate. As described above in FIG. 17B, when the second substrate having the second semiconductor devices 1 is stacked on the first substrate in the wafer-on-wafer manner, the second adhesive layer 77 may be provided on the bottom surface of the first substrate or the top surface of the second substrate, and the second adhesive layer 77 may be perforated by the upper terminal 108 of the second substrate.

Alternatively, as illustrated in FIG. 17A, when the individual second semiconductor device 2 is stacked in the chip-on-wafer manner, the second adhesive layer 75 may be an underfill which fills a space between the second semiconductor device 2 and the first substrate and further covers at least portions of sidewalls of the second semiconductor device 2. The second adhesive layer 75 may include an epoxy molding compound (EMC).

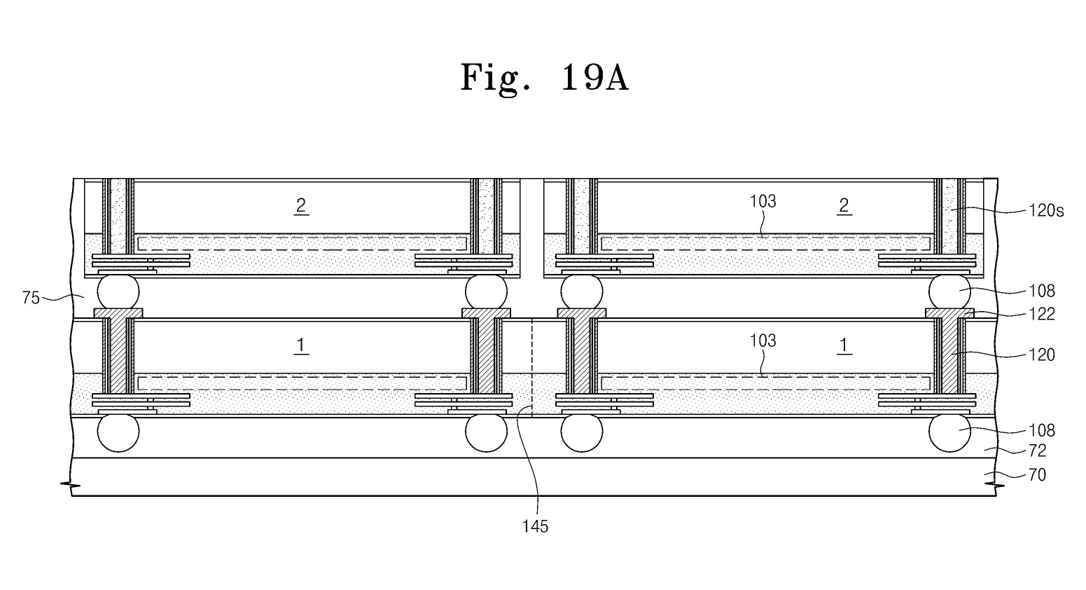

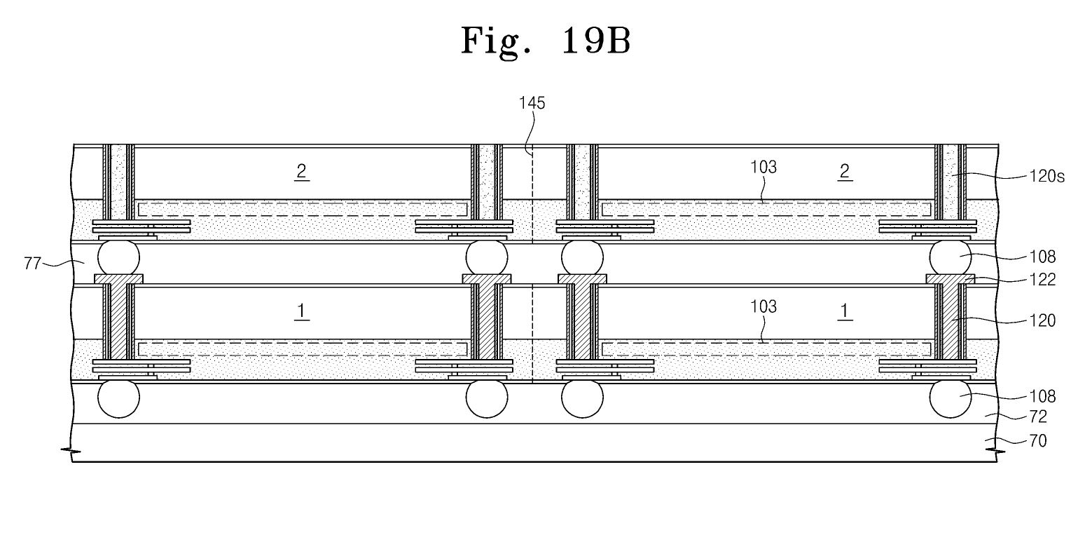

Referring to FIGS. 19A and 19B, the first thinning process described with reference to FIG. 8 may be performed on the second semiconductor device 2 fixed by the second adhesive layer 75 or 77 to expose the sacrificial through-via 120s of the second semiconductor device 2, and the second thinning process may be performed to protrude the sacrificial through-via 120s of the second semiconductor device 2. Subsequently, as described with reference to FIGS. 10 and 11, the lower insulating layer may be formed not to cover the sacrificial through-via 120s of the second semiconductor device 2 on the bottom surface of the second semiconductor device 2.

By the first and second thinning processes, the second semiconductor device 2 may have a thin thickness of about 50 μm or less.

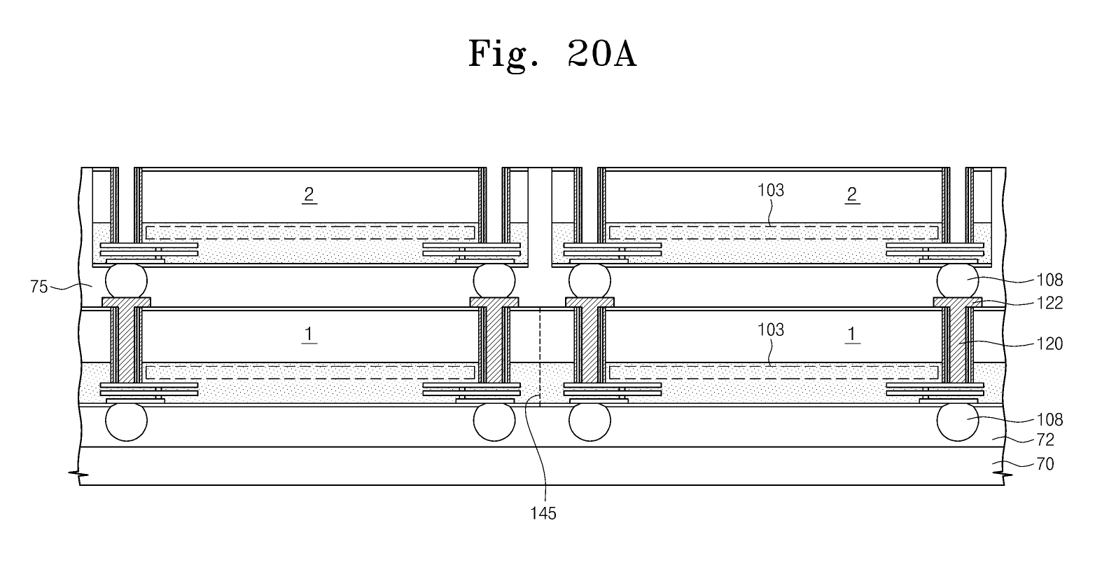

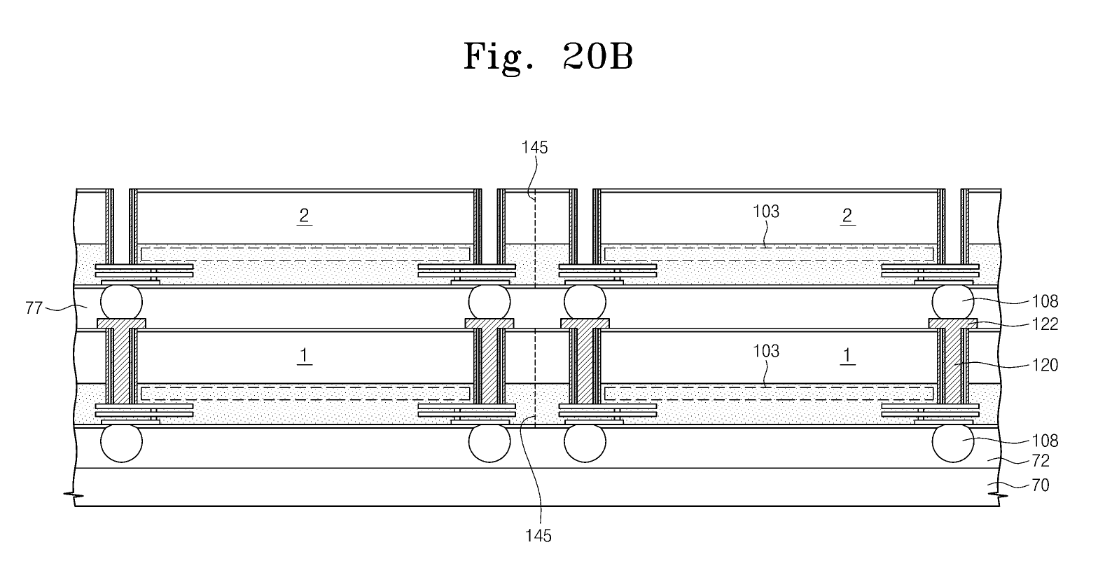

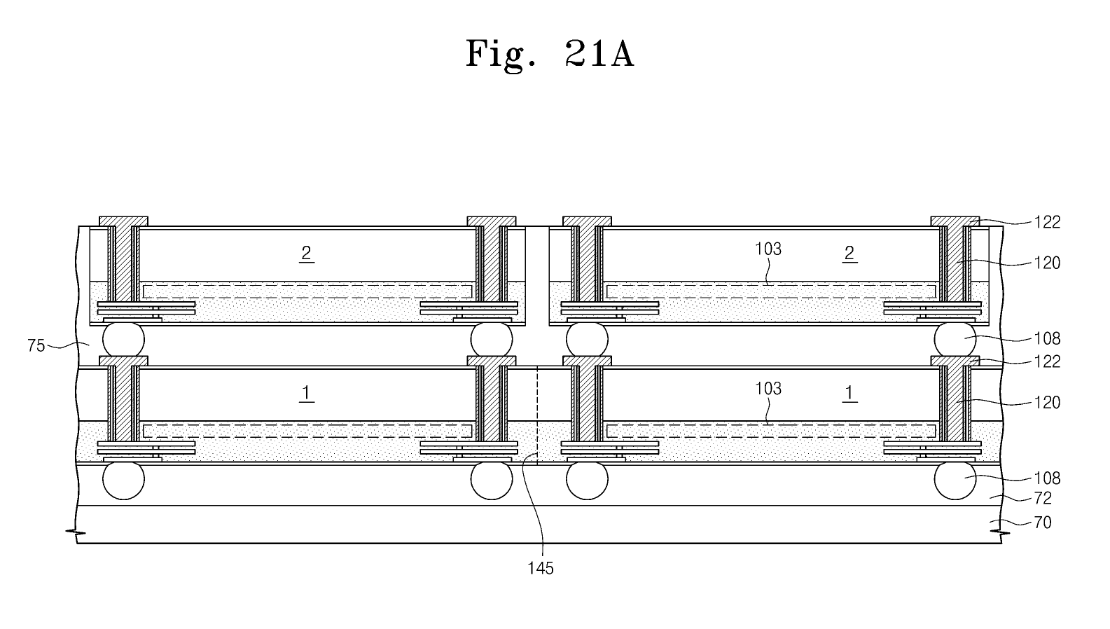

Referring to FIGS. 20A and 20B, the sacrificial through-via 120s of the second semiconductor device 2 may be selectively removed, as mentioned with reference to FIG. 12.

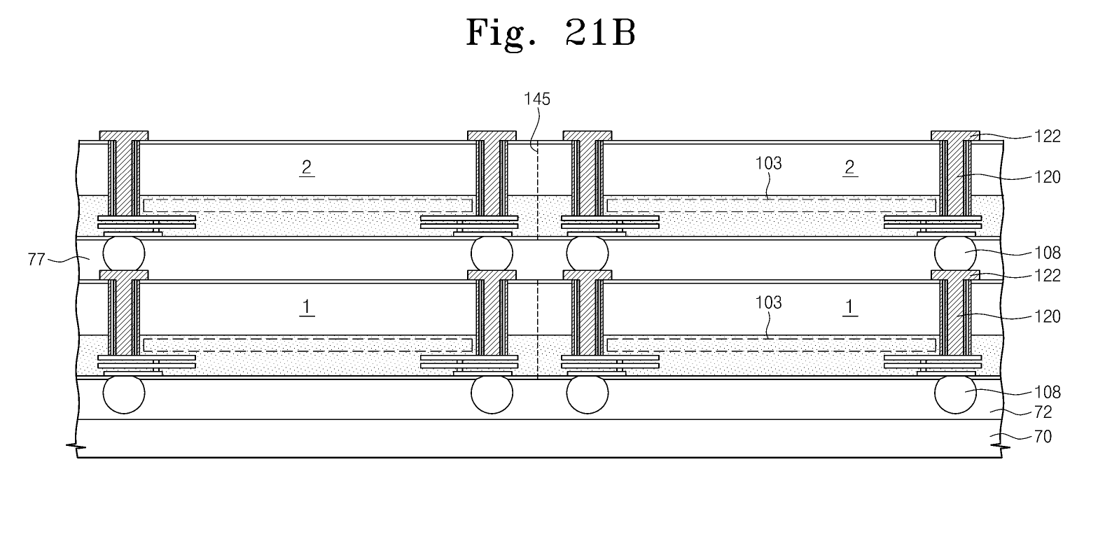

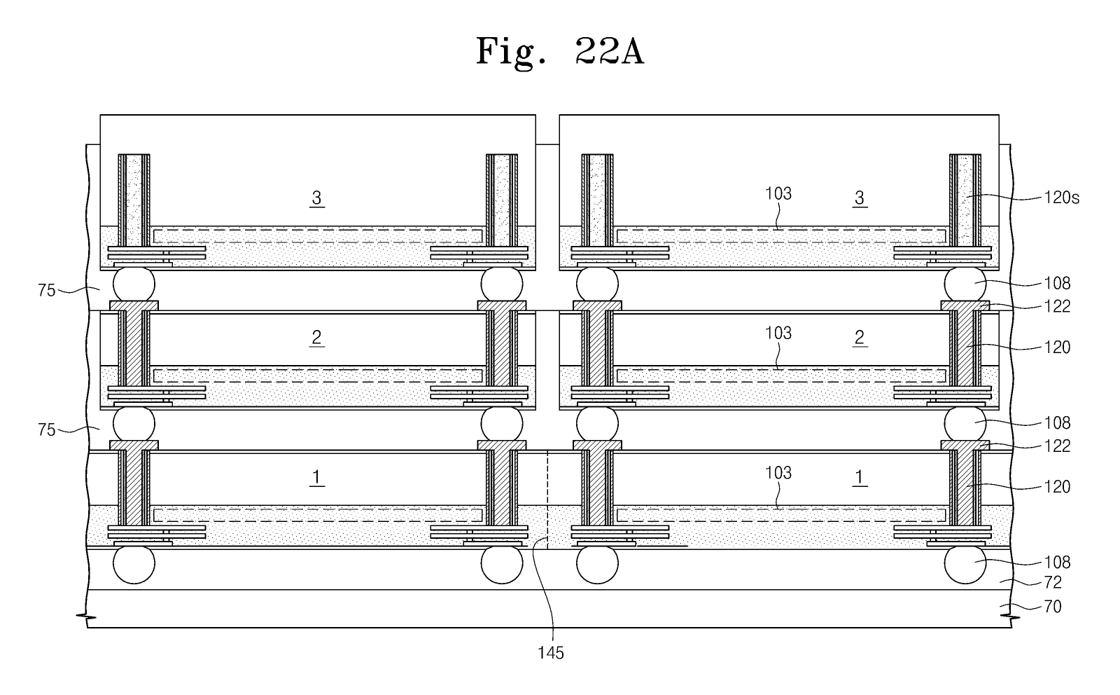

Referring to FIGS. 21A and 21B, a conductive through-via 120 of the second semiconductor device 2 may be formed in the second via-hole where the sacrificial through-via 120s is removed, as described with reference to FIGS. 13 to 16. At this time, a lower terminal 122 electrically connected to the through-via 120s may be formed on the bottom surface of the second semiconductor device 2. The through-via 120s and the lower terminal 122 of the second semiconductor device 2 may be formed at the same time.

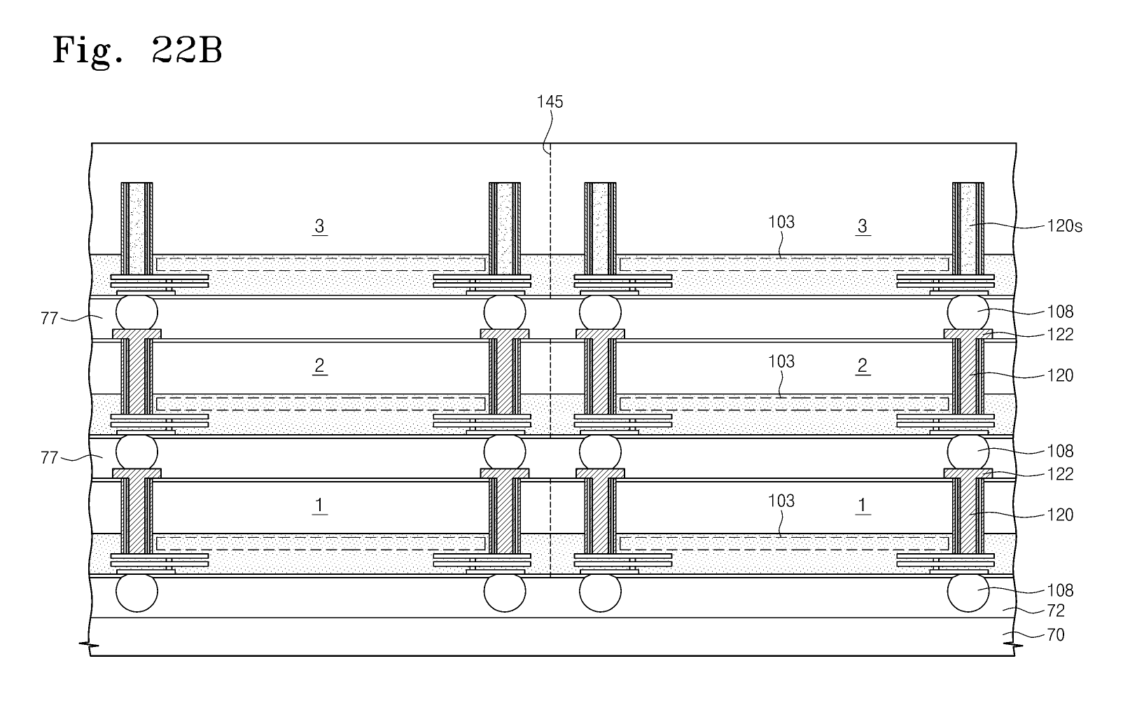

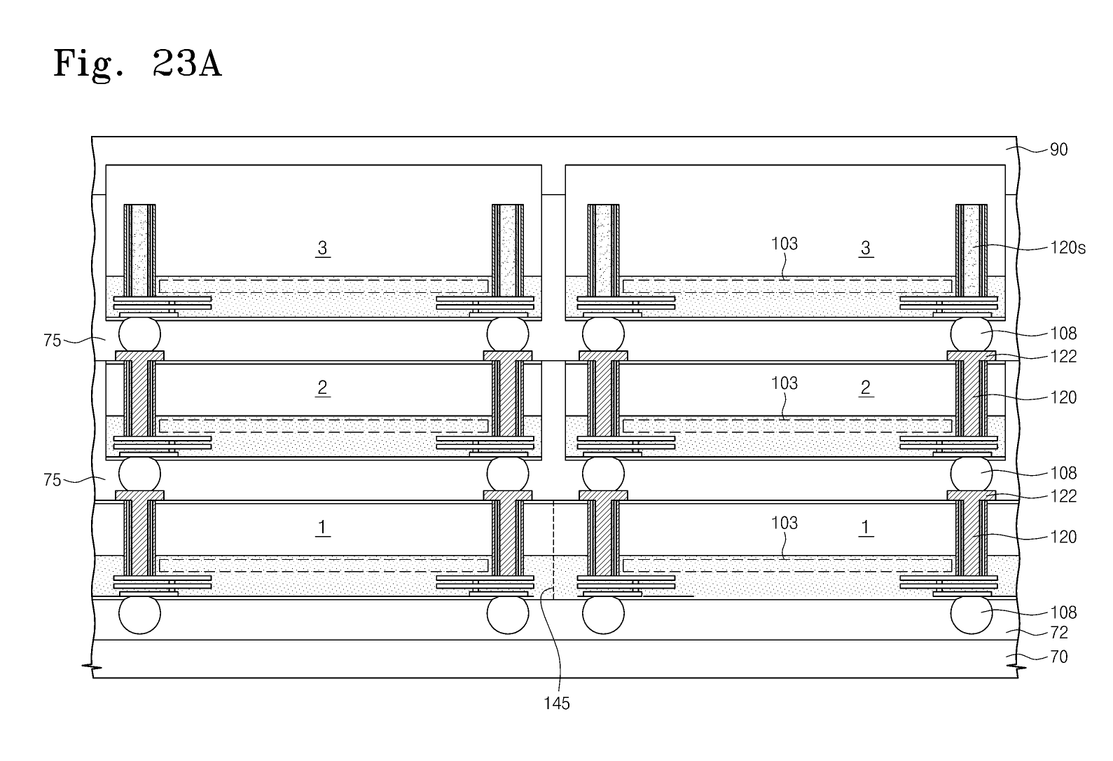

Referring to FIGS. 22A and 22B, a third semiconductor device 3 may be stacked on the second semiconductor device 2 with a second adhesive layer 75 or 77 therebetween. The third semiconductor device 3 may have a third sacrificial through-via 120s filling a third via-hole extending from a top surface toward a bottom surface of the third semiconductor device 3. Additionally, the third semiconductor device 3 may have an upper terminal 108 disposed on the top surface of the third semiconductor device 3. The upper terminal 108 of the third semiconductor device 3 may be electrically connected to the lower terminal of the second semiconductor device 2.

A thickness of the stacked third semiconductor device 3 may have a range of about 300 μm to about 500 μm. Due to the thick thickness of the third semiconductor device 3, attaching, detaching, transferring and/or mounting processes may be stably performed without warpage of the third semiconductor device 2 even though a carrier is not used.

Even though not shown in the drawings, the processes described with reference to FIGS. 19A, 19B, 20A, 20B, 21A, and 21B may be performed to replace third sacrificial through-via 120s of the third semiconductor device 3 with a conductive through-via. Subsequently, a fourth semiconductor device may be additionally stacked on the third semiconductor device 3 with an adhesive layer therebetween.

A thickness of the stacked fourth semiconductor device may have a range of about 300 μm to about 500 μm. Due to the thick thickness of the fourth semiconductor device, attaching, detaching, transferring and/or mounting processes may be stably performed without warpage of the fourth semiconductor device even though a carrier is not used.

As illustrated in FIGS. 22A and 22B, if the fourth semiconductor device is not stacked on the third semiconductor device 3, the processes for the formation of the conductive through-via of FIGS. 19A, 19B, 20A, 20B, 21A, and 21B may not performed on the third semiconductor device 3.

As a result, a semiconductor device stack structure may be realized to include the second semiconductor device 2 and the third semiconductor device 3 sequentially stacked on the first substrate bonded to the carrier 70.

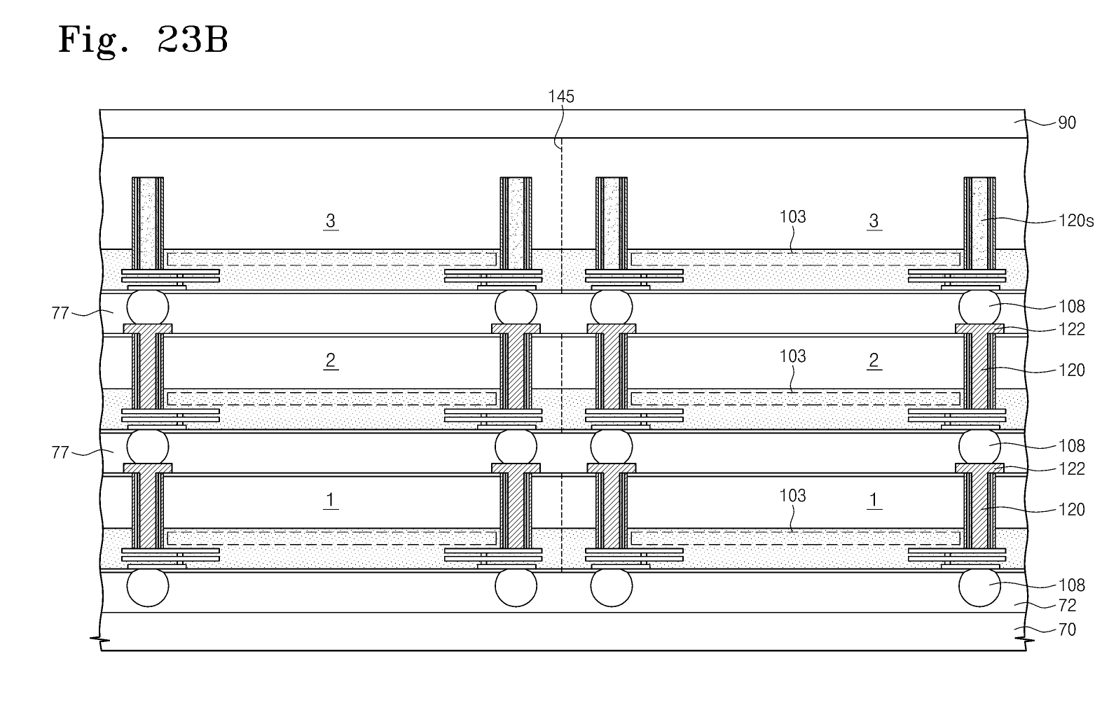

Referring to FIGS. 23A and 23B, a first molding part 90 may be formed to cover the bottom surface of the first substrate, the second semiconductor device 2, and the third semiconductor device 3. The first molding part 90 may include an epoxy molding compound. The first molding part 90 may protect the first substrate, the second semiconductor device 2, and the third semiconductor device 3 from external circumstances.

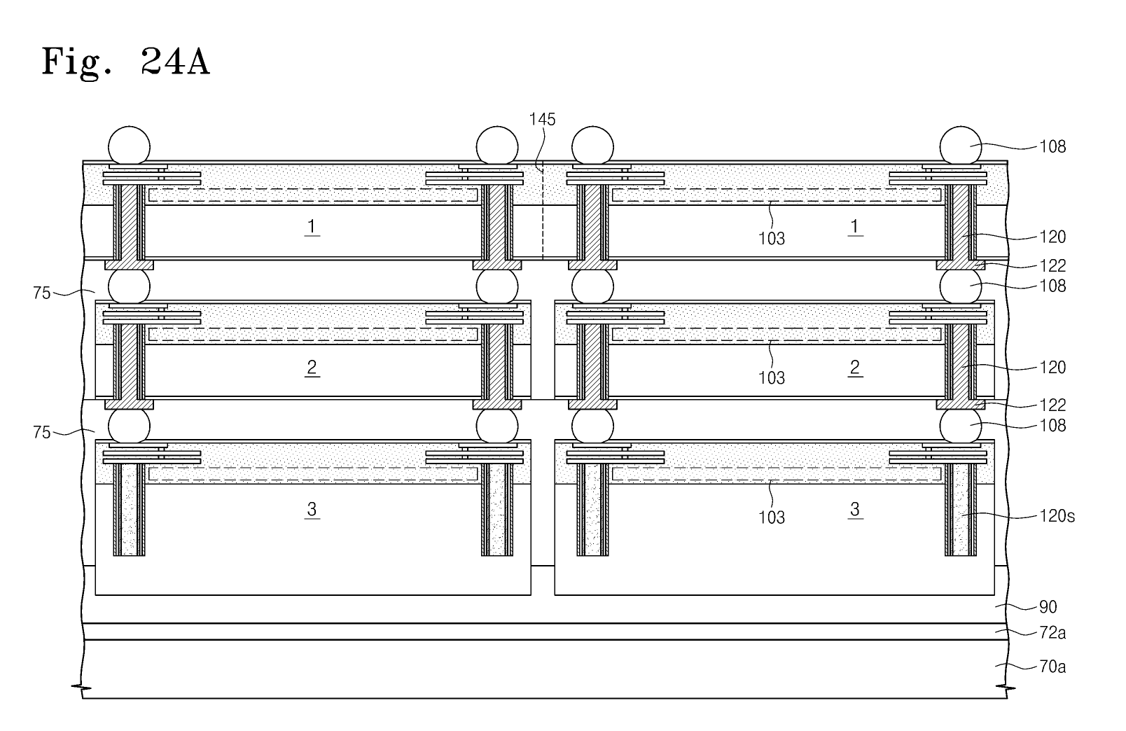

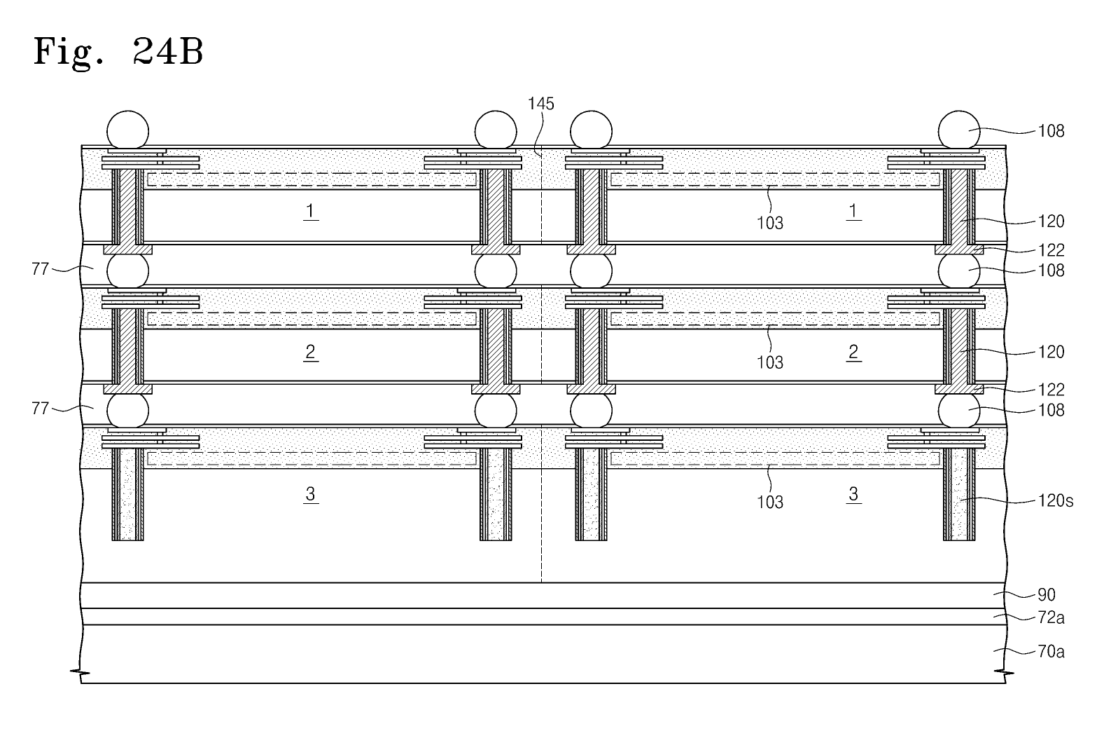

Referring to FIGS. 24A and 24B, the semiconductor device stack structure may be separated from the carrier 70, and the first molding part 90 of the semiconductor device stack structure may be bonded to a separation support substrate 70a with a third adhesive layer 72a therebetween.

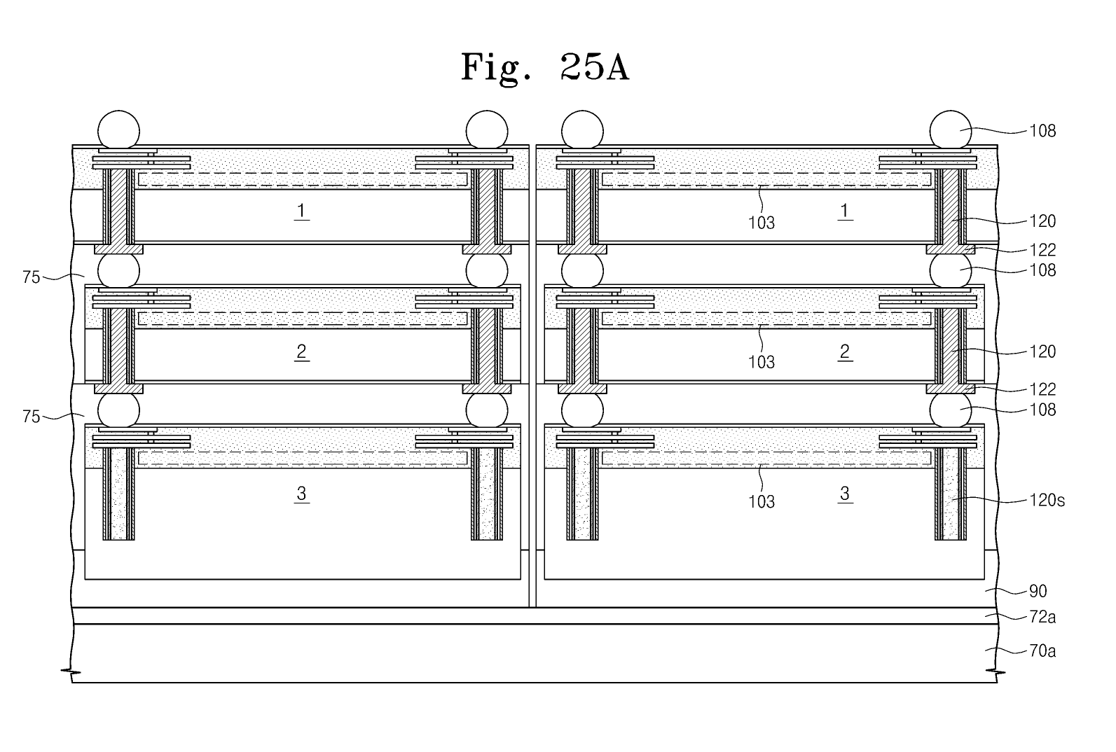

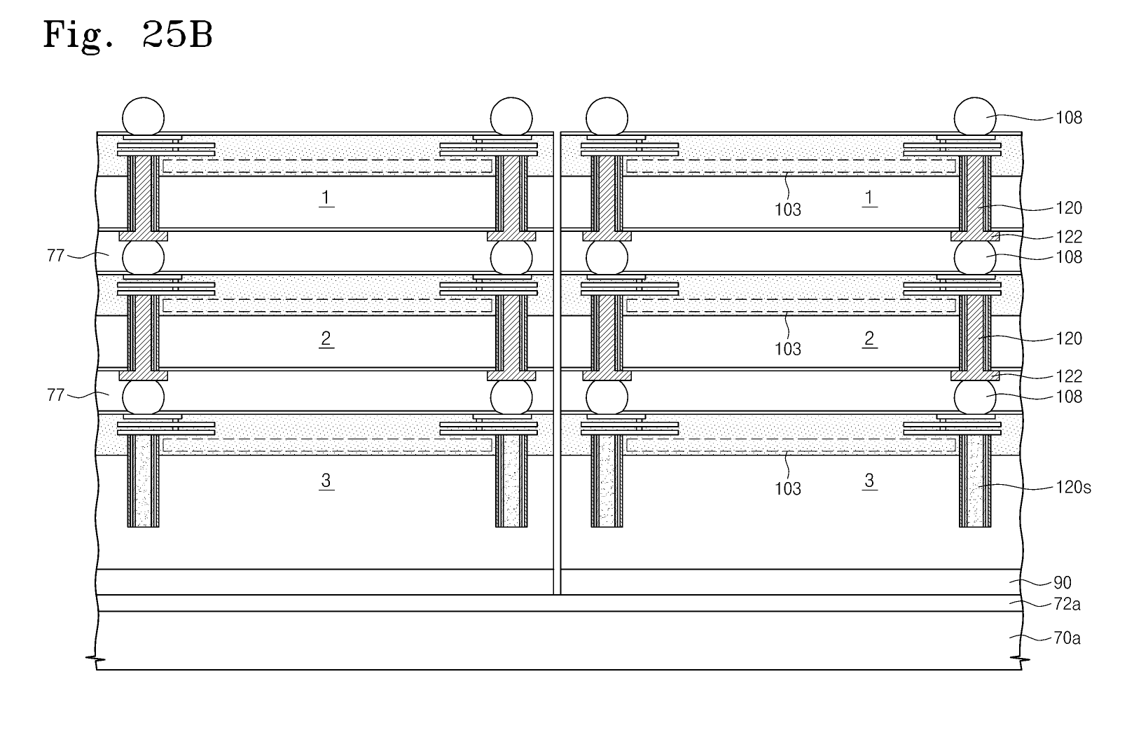

Referring to FIGS. 25A and 25B, the first molding part 90, the second adhesive layer 75 or 77, and the substrate may be cut along a scribe lane 145 of the first substrate, and the second semiconductor device 2, and the third semiconductor device 3. Thus, individual stack semiconductor devices may be separated from each other.

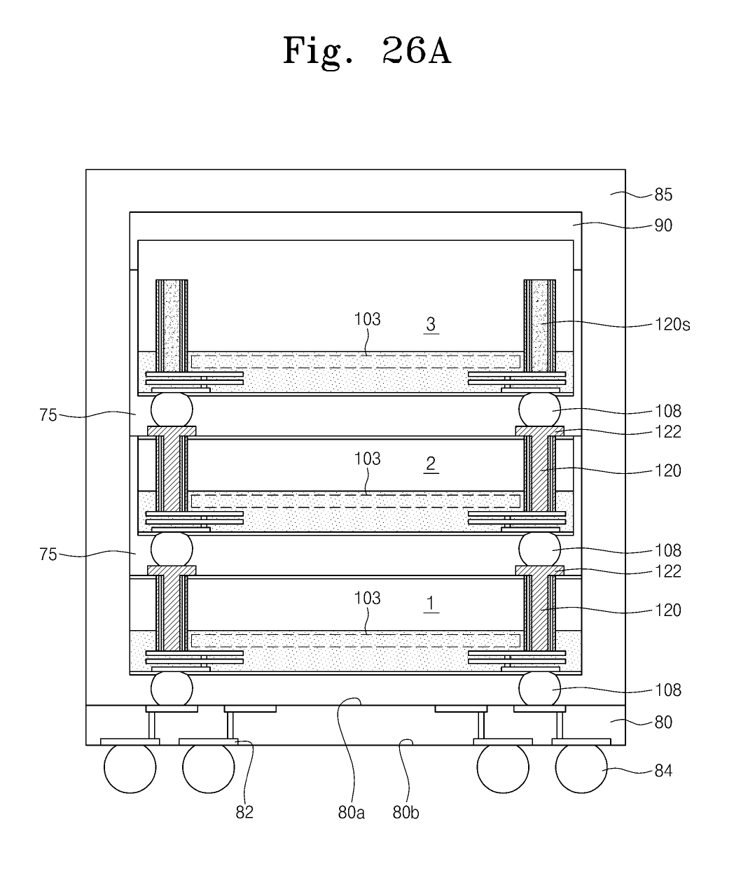

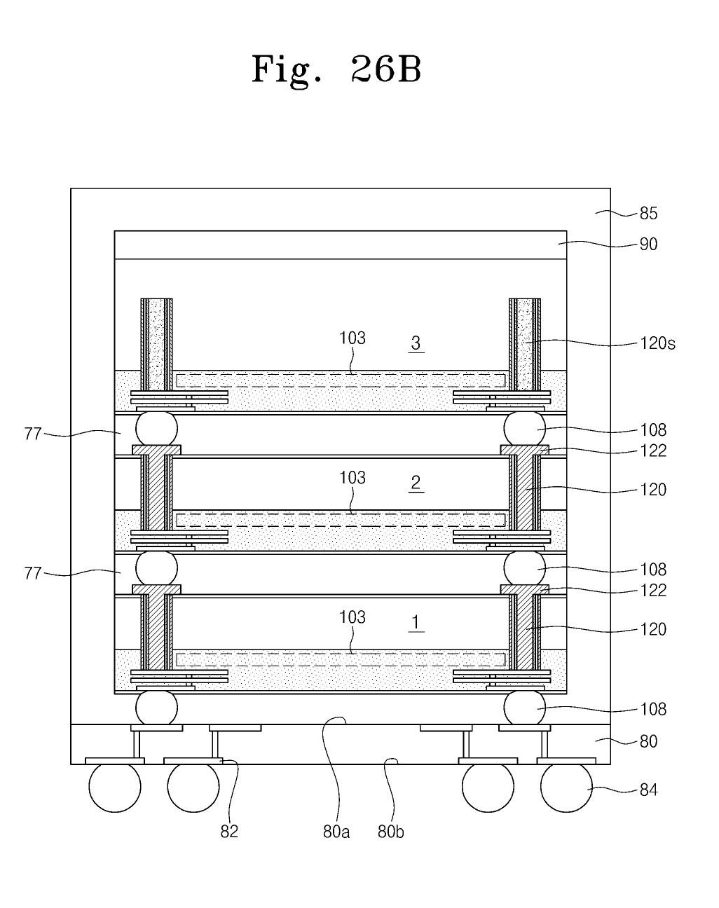

Referring to FIGS. 26A and 26B, the stack semiconductor device may be mounted on a wiring substrate 80 in such a way that the upper terminal 108 of the first substrate of the stack semiconductor device faces the wiring substrate 80. The wiring substrate 80 may include a top surface 80a, a bottom surface 80b opposite to the top surface 80a, and electrical connection wires 82 therein. The wiring substrate 80 may be a printed circuit board (PCB). The wiring substrate 80 may further include at least one solder ball 84 bonded to the bottom surface 80b and electrically connected to the electrical connection wire 82. The wiring substrate 80 may be electrically connected to an external device through the solder ball 84.

A second molding part 85 may be formed to cover the top surface 80a of the wiring substrate 85 and the stack semiconductor device. The second molding part 85 may include an epoxy molding compound. The second molding part 85 may protect the stack semiconductor device from external circumstances.

In the method of the semiconductor package according to an example embodiment of the inventive concepts, the sacrificial through-via formed by the via-middle scheme may be replaced with the conductive through-via formed by the last-middle scheme after the formation of the metal interconnection. Thus, the substrate including the semiconductor devices or the semiconductor device may be thinned without the metal contamination. As a result, the stably thinned semiconductor package having improved reliability and the method of fabricating the same may be provided.

Additionally, since the sacrificial through-via formed by the via-middle scheme may be replaced with the conductive through-via formed by the last-middle scheme after the formation of the metal interconnection, it is possible to prevent or inhibit the pumping phenomenon of the conductive through-via, which may be caused by thermal stress and/or thermal expansion. Thus, the stably thinned semiconductor package having improved reliability and the method of fabricating the same may be provided.

Moreover, since the sacrificial through-via formed by the via-middle scheme may be replaced with the conductive through-via formed by the last-middle scheme after the formation of the metal interconnection, the substrate may be stably tinned and the metal contamination on the bottom surface of the substrate may be prevented or inhibited. As a result, the semiconductor package having improved reliability may be stably thinned.

Furthermore, the semiconductor device having the thickness capable of stably performing the detaching, attaching, transferring and mounting processes without use of a carrier may be stacked and thinned. Thus, the semiconductor device may be thinned at a relatively low cost. As a result, it is possible to provide the fabricating method capable of stably thinning the semiconductor package and of reducing fabricating costs.

FIG. 27 is a plan view illustrating a package module according to an example embodiment of the inventive concepts.

Referring to FIG. 27, a package module 700 may include a module board 702 including external connection terminals 708, a semiconductor chip 704 mounted on the module board 702, and a quad flat package (QFP) type semiconductor package 706. The semiconductor chip 704 may include one of the semiconductor devices according to the aforementioned example embodiments of the inventive concepts, and the semiconductor package 706 may include one of the semiconductor packages according to the aforementioned example embodiments of the inventive concepts. The package module 700 may be connected to an external electronic device through the external connection terminals 708 thereof.

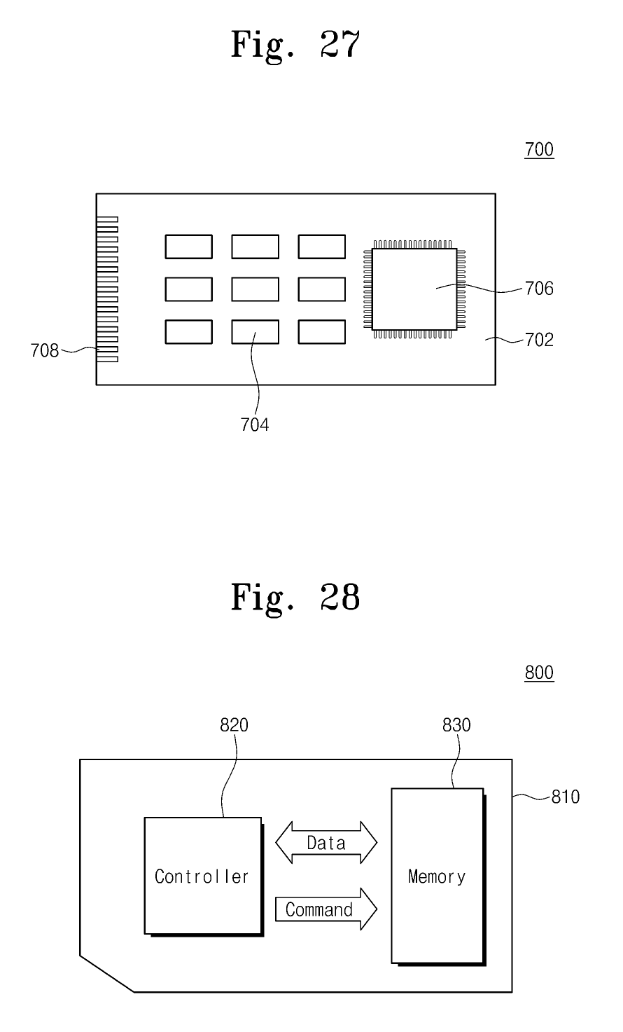

FIG. 28 is a schematic block diagram illustrating a memory card according to an example embodiment of the inventive concepts.

Referring to FIG. 28, a memory card 800 may include a controller 820 and a memory device 830 in a housing. The controller 820 and the memory device 830 may exchange electrical signals with each other. For example, the controller 820 and the memory device 830 may exchange data with each other by commands of the controller 820. Thus, the memory card 800 may store data in the memory device 830 or may output data from the memory device 830 to an external system.

The controller 820 and/or the memory device 830 may include at least one of the semiconductor devices and the semiconductor packages according to the aforementioned example embodiments of the inventive concepts. For example, the controller 820 may include a system in package, and the memory device 830 may include a multi-chip package. Alternatively, the controller 820 and the memory device 830 may be formed into a stack type package. The memory card 800 may be used as a data storage medium of various portable devices. For example, the memory card 800 may be realized as a multimedia card (MMC) or a secure digital (SD) card.

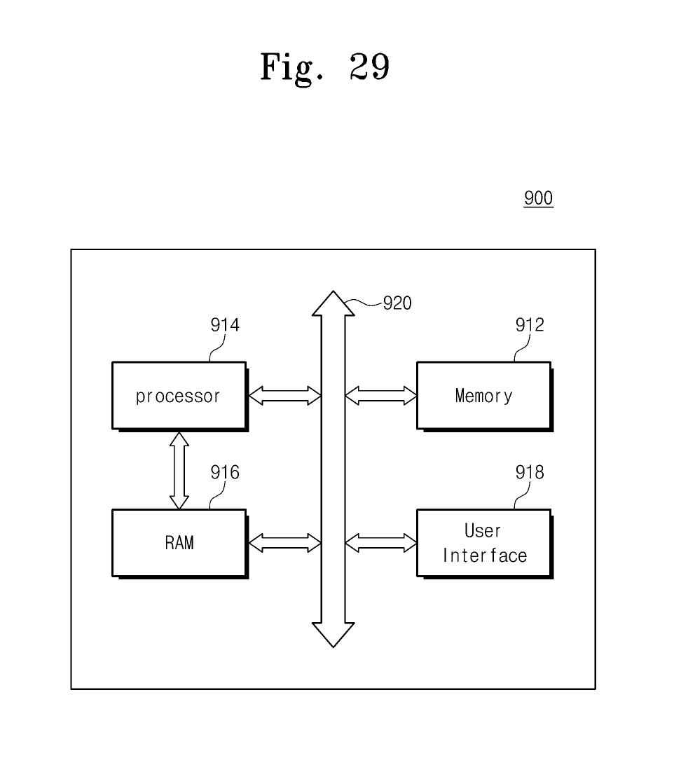

FIG. 29 is a schematic block diagram illustrating an electronic system according to an example embodiment of the inventive concepts.

Referring to FIG. 29, an electronic system 900 may include at least one of the semiconductor device and the semiconductor packages according to the aforementioned example embodiments of the inventive concepts. The electronic system 900 may include a mobile device or a computer. For example, the electronic system 900 may include a memory system 912, a processer 914, a random access memory (RAM) device 916, and a user interface unit 918. At least two of the memory system 912, the processor 914, the RAM device 916, and the user interface unit 918 may communicate with each other through the data bus 920. The processor 914 may execute a program and may control the electronic system 900. The RAM device 916 may be used as an operation memory device of the processor 914. Each of the processor 914 and the RAM device 916 may include at least one of the semiconductor devices and the semiconductor packages according to the aforementioned example embodiments of the inventive concepts. Alternatively, the processor 914 and the RAM device 916 may be included in one package. The user interface unit 918 may be used for data input/data output of the electronic system 900. The memory system 912 may store a coder for operation of the processor 914, data processed by the processor 914, and/or data inputted from an external system. The memory system 912 may include a controller and a memory device. The memory system 912 may include substantially the same structure as the memory card 800 of FIG. 28.

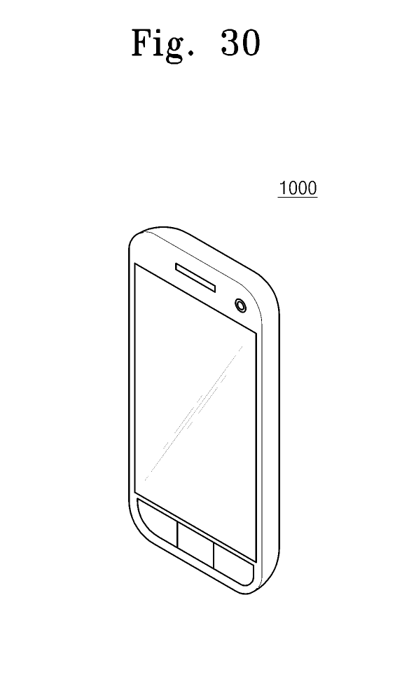

The electronic system 900 may be applied to electronic control devices of various electronic devices. FIG. 30 illustrates a mobile phone 1000 applied with the electronic system 900 of FIG. 29. In other embodiments, the electronic system 900 of FIG. 29 may be applied to portable notebooks, MP3 players, navigations, solid state disks (SSDs), cars, and/or household appliances.

According to some example embodiments of the inventive concepts, the sacrificial through-via formed by the via-middle scheme may be replaced with the conductive through-via formed by the last-middle scheme after the formation of the metal interconnection. Thus, the substrate may be thinned without the metal contamination on the bottom surface of the substrate. As a result, the stably thinned semiconductor device having improved reliability may be realized.

Additionally, since the sacrificial through-via formed by the via-middle scheme may be replaced with the conductive through-via formed by the last-middle scheme after the formation of the metal interconnection, it is possible to prevent or inhibit the pumping phenomenon of the conductive through-via, which may be caused by thermal stress and/or thermal expansion. Thus, the stably thinned semiconductor device having improved reliability may be provided.

Moreover, since the semiconductor device has the conductive through-via formed by the replacement process using the sacrificial through-via, the substrate may be stably tinned and the metal contamination on the bottom surface of the substrate may be prevented or inhibited. As a result, the semiconductor device having improved reliability may be stably thinned.

While the inventive concepts have been described with reference to example embodiments, it will be apparent to those skilled in the art that various changes and modifications may be made without departing from the spirit and scope of the inventive concepts. Therefore, it should be understood that the above embodiments are not limiting, but illustrative. Thus, the scope of the inventive concepts is to be determined by the broadest permissible interpretation of the following claims and their equivalents, and shall not be restricted or limited by the foregoing description.

What is claimed is:

1. A method of fabricating a semiconductor device comprising:
forming a first sacrificial through-via filling a first via-hole in a first substrate, the first sacrificial through-via extending from a first surface of the first substrate toward a second surface of the first substrate opposite the first surface;
bonding the first surface of the first substrate to a carrier;
exposing an end portion of the first sacrificial through-via adjacent to the second surface of the first substrate;
selectively removing the first sacrificial through-via; and
forming a first conductive through-via filling the first via-hole after the selectively removing the first sacrificial through-via.

2. The method of claim 1, wherein the selectively removing removes the first sacrificial through-via by at least one of a dry etching process, a wet etching process, and a sublimating process.

3. The method of claim 2, wherein the forming a first sacrificial through-via includes forming the first sacrificial through-via of a polymer capable of being sublimated.

4. The method of claim 1, further comprising:
forming a first insulating layer on the second surface of the first substrate, the first insulating layer not covering the exposed first sacrificial through-via.

5. The method of claim 1, further comprising:
forming a via-insulating layer between the first substrate and the first sacrificial through-via.

6. The method of claim 5, further comprising:
forming an under bump metallurgy layer between the first conductive through-via and the via-insulating layer.

7. The method of claim 1, further comprising:
forming a first terminal on the first surface of the first substrate, the first terminal being electrically connected to the first conductive through-via.

8. The method of claim 7, further comprising:
forming a second terminal on the second surface of the first substrate, the second terminal being electrically connected to the first conductive through-via.

9. The method of claim 8, wherein the forming a first conductive through-via and the forming a second terminal are performed simultaneously.

10. The method of claim 8, further comprising:
stacking a second semiconductor device on the first substrate, the second semiconductor device including,
a second sacrificial through-via filling a second via-hole in the second semiconductor device, the second sacrificial through-via extending from a first surface of the second semiconductor device toward a second surface opposite the first surface of the second semiconductor device, and
a first terminal on the first surface of the second semiconductor device, the first terminal of the second semiconductor device electrically connected to the second terminal of the first substrate;
forming an adhesive layer between the second semiconductor device and the first substrate;
exposing an end portion of the second sacrificial through-via adjacent to the second surface of the second semiconductor device;
selectively removing the second sacrificial through-via; and
forming a second conductive through-via filling the second via-hole after the selectively removing the second sacrificial through-via.

11. The method of claim 10, wherein
the second semiconductor device is an individual semiconductor device;
the forming an adhesive layer includes forming an underfill; and
the forming an adhesive layer forms the adhesive layer extending to cover at least portions of sidewalls of the second semiconductor device.

12. The method of claim 10, wherein
the stacking stacks a second semiconductor device on a second substrate; and
the forming an adhesive layer forms a non-conductive film.

13. The method of claim 10, further comprising:
forming a molding part covering the second semiconductor device and the second surface of the first substrate.

14. The method of claim 13, further comprising:
cutting the molding part and the first substrate to form stacked semiconductor devices separate from each other.

15. The method of claim 14, further comprising:
mounting the stacked semiconductor devices on a wiring substrate, the first surface of the first substrate of the stacked semiconductor devices facing the wiring substrate.

16. A method of fabricating a semiconductor device, the method comprising:
forming a sacrificial through-via filling a via-hole in a substrate, the sacrificial through-via extending from a first surface of the substrate toward a second surface of the substrate opposite the first surface;
forming a metal interconnection on the first surface of the substrate, the metal interconnection electrically connected to the sacrificial through-via; and
after the forming a metal interconnection,
selectively removing the sacrificial through-via from the via-hole, and
forming a conductive through-via therein.

17. The method of claim 16, further comprising:
bonding the first surface of the substrate to a carrier; and
exposing an end portion of the sacrificial through-via adjacent to the second surface of the substrate before the selectively removing the sacrificial through-via.

18. The method of claim 16, wherein the selectively removing removes the sacrificial through-via by at least one of a dry etching process, a wet etching process, and a sublimating process.

19. The method of claim 16, further comprising:
forming a via-insulating layer between the substrate and the sacrificial through-via.

20. The method of claim 19, further comprising:
forming an under bump metallurgy layer between the conductive through-via and the via-insulating layer.
